(19) United States
(12) Patent Application Publication
(10) Pub. No.: US 2024/0306495 A1
(43) Pub. Date: Sep. 12, 2024

(54) LIGHT EMITTING DEVICE AND DISPLAYING DEVICE

(71) Applicant: BOE Technology Group Co., Ltd., Beijing (CN)

(72) Inventors: Siqi Wang, Beijing (CN); Haiyan Sun, Beijing (CN); Lixia Qiu, Beijing (CN); Xiaojin Zhang, Beijing (CN); Dan Wang, Beijing (CN)

(73) Assignee: BOE Technology Group Co., Ltd., Beijing (CN)

(21) Appl. No.: 18/025,982

(22) PCT Filed: May 30, 2022
(86) PCT No.: PCT/CN2022/096048

§ 371 Date: Mar. 13, 2023

(51) Int. Cl. H10K 85/60; H10K 50/18; H10K 101/40

(52) U.S. Cl. CPC H10K 85/6572; H10K 85/615; H10K 85/636; H10K 85/654; H10K 85/657; H10K 85/6574; H10K 50/181; H10K 2101/40

(57) ABSTRACT

The present application provides a light emitting device and a displaying device, which relates to the technical field of displaying. The light emitting device includes a first electrode and a second electrode; a luminescent layer, located between the first electrode and the second electrode, including a host material and a thermally activated delayed-fluorescence material; and an electron blocking layer, located between the luminescent layer and the first electrode; and 0.1 eV<|HOMO_{EBL}−HOMO_{Host}|≤0.3 eV, wherein HOMO_{EBL} refers to an energy value of a highest occupied molecular orbital HOMO of a material of the electron blocking layer, and HOMO_{Host} refers to an energy value of a highest occupied molecular orbital HOMO of the host material. The light emitting device has a high luminous efficiency and a long service life.

### TECHNICAL FIELD

The present application relates to the technical field of displaying, and particularly relates to a light emitting device and a displaying device.

### BACKGROUND

Organic thermally activated delayed fluorescence (TADF) materials have advantages such as a high electroluminescent efficiency and simple molecular design, have already been extensively used as the emitter of organic light emitting diodes (OLED), and have been paid extensive attention in the field of displaying. However, the luminous efficiencies and the service lives of the organic light emitting diodes having the thermally activated delayed-fluorescence materials in the related art should be further increased.

### SUMMARY

The embodiments of the present application employ the following technical solutions:

In the first aspect, an embodiment of the present application provides a light emitting device, wherein the light emitting device comprises:
a first electrode and a second electrode;
a luminescent layer, located between the first electrode and the second electrode, comprising a host material and a thermally activated delayed-fluorescence material; and
an electron blocking layer, located between the luminescent layer and the first electrode; and

0.1eV<|HOMO_{EBL}−HOMO_{Host}|≤0.3 eV,
wherein HOMO_{EBL} refers to an energy value of a highest occupied molecular orbital HOMO of a material of the electron blocking layer, and HOMO_{Host} refers to an energy value of a highest occupied molecular orbital HOMO of the host material.

In some embodiments of the present application, the light emitting device further comprises a hole blocking layer, and the hole blocking layer is located between the luminescent layer and the second electrode; and

0.1eV<|LUMO_{HBL}−LUMO_{Host}|≤0.3 eV,
wherein LUMO_{HBL} refers to an energy value of a lowest unoccupied molecular orbital LUMO of a material of the hole blocking layer, and LUMO_{Host} refers to an energy value of a lowest unoccupied molecular orbital LUMO of the host material.

In some embodiments of the present application, T1_{EBL}−T1_{TADF}≥0.1 eV, and S1_{EBL}−S1_{TADF}>0,
wherein T1_{EBL} refers to an energy value of a first-triplet-state energy level of the material of the electron blocking layer, T1_{TADF} refers to an energy value of a first-triplet-state energy level of the thermally activated delayed-fluorescence material, S1_{EBL} refers to an energy value of a first-singlet-state energy level of the material of the electron blocking layer, and S1_{TADF} refers to an energy value of a first-singlet-state energy level of the thermally activated delayed-fluorescence material.

In some embodiments of the present application, T1_{HBL}−T1_{TADF}>0, and S1_{HBL}−S1_{TADF}>0,
wherein T1_{HBL} refers to an energy value of a first-triplet-state energy level of a material of a hole blocking layer, and S1_{HBL} refers to an energy value of a first-singlet-state energy level of the material of the hole blocking layer.

In some embodiments of the present application, the material of the electron blocking layer, the host material and the material of the hole blocking layer individually comprise:

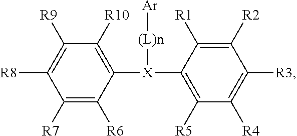

wherein X comprises one of a boron atom, a carbon atom, a nitrogen atom, an oxygen atom, a silicon atom, a phosphorus atom and a sulphur atom, L comprises one of substituted or unsubstituted C6-C20 arylene and substituted or unsubstituted C3-C30 heteroarylene, and n is one of 0, 1 and 2.

In some embodiments of the present application, R1-R10 individually comprise one of hydrogen, C-C12 alkyl, substituted or unsubstituted C6-C30 arylene and substituted or unsubstituted C3-C30 heteroarylene.

In some embodiments of the present application, at least one pair of two neighboring groups among R1-R10 are connected to form a ring.

In some embodiments of the present application, Ar comprises one of hydrogen, C1-C12 alkyl, substituted or unsubstituted C6-C30 arylene and substituted or unsubstituted C3-C30 heteroarylene.

In some embodiments of the present application, the material of the hole blocking layer comprises:

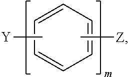

wherein Y and Z individually comprise hydrogen, diplogen, halogen group, nitrile group, nitro, hydroxyl, carbonyl, ester group, imide group, amino, substituted or unsubstituted C3-C30 silyl, substituted or unsubstituted boryl, substituted or unsubstituted C1-C30 alkyl, substituted or unsubstituted C3-C30 cycloalkyl, substituted or unsubstituted alkoxy, substituted or unsubstituted aryloxy, substituted or unsubstituted alkylsulfenyl, substituted or unsubstituted arylsulfenyl, substituted or unsubstituted alkylsulfonyl, substituted or unsubstituted C6-C30 arylsulfonyl, substituted or unsubstituted alkenyl, substituted or unsubstituted aralkyl, substituted or unsubstituted aralkenyl, substituted or unsubstituted alkaryl, substituted or unsubstituted alkylamido, substituted or unsubstituted C1-C30 aralkylamido, substituted or unsubstituted C6-C30 heteroarylamido, substituted or unsubstituted C6-C30 arylamido, substituted or unsubstituted C6-C30 arylheteroarylamido, substituted or unsubstituted C6-C30 arylphosphino, substituted or unsubstituted phosphine oxide group, substituted or unsubstituted C6-C30 aryl, substituted or unsubstituted heterocyclic group, substituted or unsubstituted C1-C30 alkyl C6-C30 diarylsilyl, and substituted or unsubstituted C3-C30 monocyclic or polycyclic alicyclic ring or aromatic ring; and
if at least one of X and Y comprises the substituted or unsubstituted C3-C30 monocyclic or polycyclic alicyclic ring or aromatic ring, the alicyclic ring or aromatic ring comprises at least one heteroatom, and the heteroatom comprises oxygen atom, sulphur atom or nitrogen atom.

In some embodiments of the present application, m is greater than or equal to 3;
if m=3,

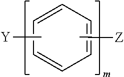

comprises:

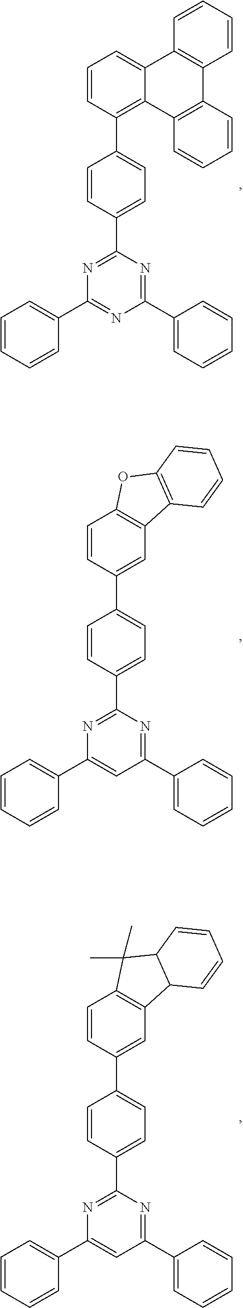 [SMILES: c1ccc(-c2nc(-c3ccccc3)nc(-c3ccc(-c4cccc5c6ccccc6c6ccccc6c45)cc3)n2)cc1 ; c1ccc(-c2cc(-c3ccccc3)nc(-c3ccc(-c4ccc5oc6ccccc6c5c4)cc3)n2)cc1 ; CC1(C)c2ccc(-c3ccc(-c4nc(-c5ccccc5)cc(-c5ccccc5)n4)cc3)cc2C2C=CC=CC21]

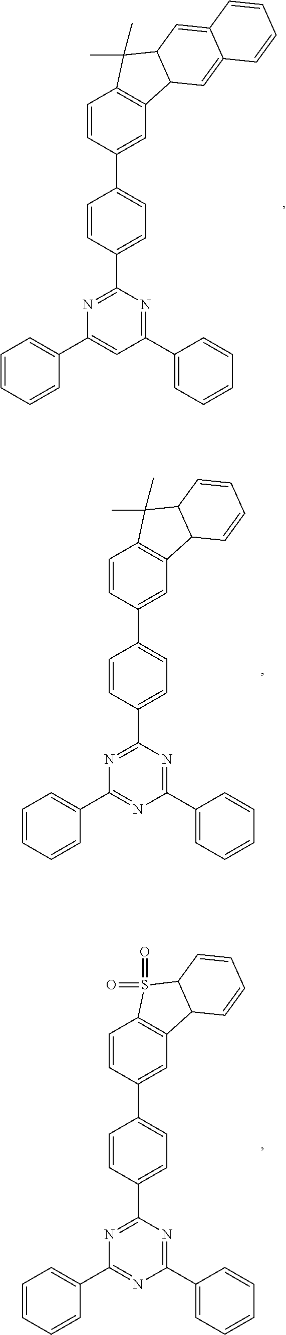 [SMILES: CC1(C)c2ccc(-c3ccc(-c4nc(-c5ccccc5)cc(-c5ccccc5)n4)cc3)cc2C2C=c3ccccc3=CC21 ; CC1(C)c2ccc(-c3ccc(-c4nc(-c5ccccc5)nc(-c5ccccc5)n4)cc3)cc2C2C=CC=CC21 ; O=S1(=O)c2ccc(-c3ccc(-c4nc(-c5ccccc5)nc(-c5ccccc5)n4)cc3)cc2C2C=CC=CC21]

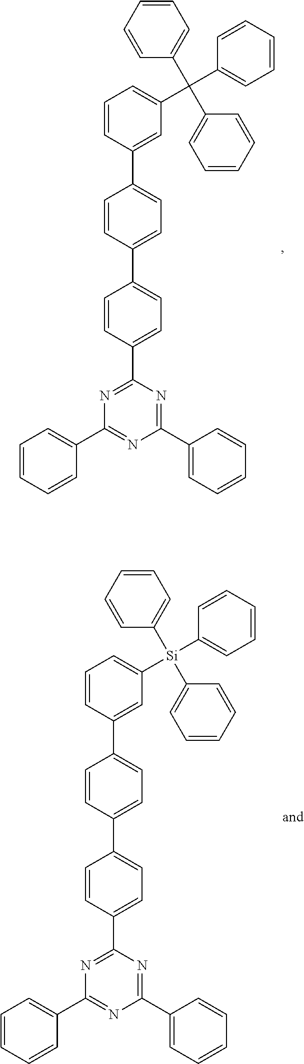 [SMILES: c1ccc(-c2nc(-c3ccccc3)nc(-c3ccc(-c4ccc(-c5cccc(C(c6ccccc6)(c6ccccc6)c6ccccc6)c5)cc4)cc3)n2)cc1 ; c1ccc(-c2nc(-c3ccccc3)nc(-c3ccc(-c4ccc(-c5cccc([Si](c6ccccc6)(c6ccccc6)c6ccccc6)c5)cc4)cc3)n2)cc1]

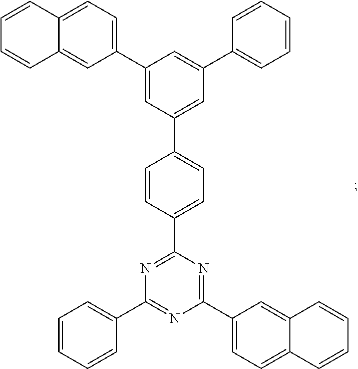 [SMILES: c1ccc(-c2cc(-c3ccc(-c4nc(-c5ccccc5)nc(-c5ccc6ccccc6c5)n4)cc3)cc(-c3ccc4ccccc4c3)c2)cc1]

and
if m=4,

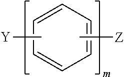

comprises:

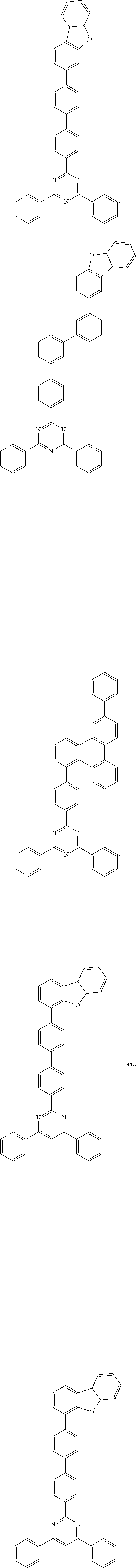 [SMILES: C1=CC2Oc3cc(-c4ccc(-c5ccc(-c6nc(-c7ccccc7)nc(-c7ccccc7)n6)cc5)cc4)ccc3C2C=C1 ; C1=CC2Oc3ccc(-c4cccc(-c5cccc(-c6ccc(-c7nc(-c8ccccc8)nc(-c8ccccc8)n7)cc6)c5)c4)cc3C2C=C1 ; c1ccc(-c2ccc3c4ccccc4c4c(-c5ccc(-c6nc(-c7ccccc7)nc(-c7ccccc7)n6)cc5)cccc4c3c2)cc1 ; C1=CC2Oc3c(-c4ccc(-c5ccc(-c6nc(-c7ccccc7)cc(-c7ccccc7)n6)cc5)cc4)cccc3C2C=C1 ; C1=CC2Oc3c(-c4ccc(-c5ccc(-c6nc(-c7ccccc7)cc(-c7ccccc7)n6)cc5)cc4)cccc3C2C=C1]

In some embodiments of the present application, the light emitting device further comprises a hole transporting layer, and the hole transporting layer is located between the electron blocking layer and the first electrode; and

0.1eV<|HOMO_{HTL}−HOMO_{EBL}|≤0.3 eV,
wherein HOMO_{HTL} refers to an energy value of a highest occupied molecular orbital HOMO of a material of the hole transporting layer.

In some embodiments of the present application, the light emitting device further comprises an electron transporting layer, and the electron transporting layer is located between the hole blocking layer and the second electrode; and

0.1eV<|LUMO_{HBL}−LUMO_{ETL}|≤0.3 eV,
wherein LUMO_{ETL} refers to an energy value of a lowest unoccupied molecular orbital LUMO of a material of the electron transporting layer.

In some embodiments of the present application, T1_{Host}≥2.45 eV, T1_{EBL}≥2.55 eV, and S1_{EBL}≥2.90 eV.

In some embodiments of the present application, |HOMO_{EBL}|≥5.6 eV, and |HOMO_{Host}|≥5.8 eV.

In some embodiments of the present application, S1_{HBL}≥3.00 eV, and T1_{HBL}≥2.60 eV.

In some embodiments of the present application, the glass-transition temperature of the material of the hole blocking layer is greater than or equal to 85° C.

In the second aspect, an embodiment of the present application provides a light emitting device, wherein the light emitting device comprises:
a first electrode and a second electrode;
a luminescent layer, located between the first electrode and the second electrode, comprising a host material and a thermally activated delayed-fluorescence material;
an electron blocking layer, located between the luminescent layer and the first electrode; and
a hole blocking layer, located between the luminescent layer and the second electrode; and
a material of the electron blocking layer and a structure of the host material individually comprise

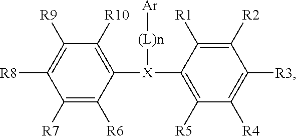

and
a structure of a material of the hole blocking layer comprises

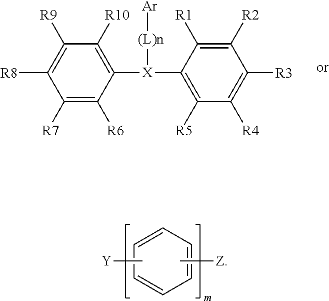

In some embodiments of the present application, X comprises one of a boron atom, a carbon atom, a nitrogen atom, an oxygen atom, a silicon atom, a phosphorus atom and a sulphur atom;
L comprises one of substituted or unsubstituted C6-C20 arylene and substituted or unsubstituted C3-C30 heteroarylene, and n is one of 0, 1 and 2; and
m is greater than or equal to 3.

In some embodiments of the present application, Y and Z individually comprise hydrogen, diplogen, halogen group, nitrile group, nitro, hydroxyl, carbonyl, ester group, imide group, amino, substituted or unsubstituted C3-C30 silyl, substituted or unsubstituted boryl, substituted or unsubstituted C1-C30 alkyl, substituted or unsubstituted C3-C30 cycloalkyl, substituted or unsubstituted alkoxy, substituted or unsubstituted aryloxy, substituted or unsubstituted alkylsulfenyl, substituted or unsubstituted arylsulfenyl, substituted or unsubstituted alkylsulfonyl, substituted or unsubstituted C6-C30 arylsulfonyl, substituted or unsubstituted alkenyl, substituted or unsubstituted aralkyl, substituted or unsubstituted aralkenyl, substituted or unsubstituted alkaryl, substituted or unsubstituted alkylamido, substituted or unsubstituted C1-C30 aralkylamido, substituted or unsubstituted C6-C30 heteroarylamido, substituted or unsubstituted C6-C30 arylamido, substituted or unsubstituted C6-C30 arylheteroarylamido, substituted or unsubstituted C6-C30 arylphosphino, substituted or unsubstituted phosphine oxide group, substituted or unsubstituted C6-C30 aryl, substituted or unsubstituted heterocyclic group, substituted or unsubstituted C1-C30 alkyl C6-C30 diarylsilyl, and substituted or unsubstituted C3-C30 monocyclic or polycyclic alicyclic ring or aromatic ring; and
if at least one of X and Y comprises the substituted or unsubstituted C3-C30 monocyclic or polycyclic alicyclic ring or aromatic ring, the alicyclic ring or aromatic ring comprises at least one heteroatom, and the heteroatom comprises oxygen atom, sulphur atom or nitrogen atom.

In some embodiments of the present application, R1-R10 individually comprise one of hydrogen, C-C12 alkyl, substituted or unsubstituted C6-C30 arylene and substituted or unsubstituted C3-C30 heteroarylene, and at least one pair of two neighboring groups among R1-R10 are connected to form a ring; and
Ar comprises one of hydrogen, C1-C12 alkyl, substituted or unsubstituted C6-C30 arylene and substituted or unsubstituted C3-C30 heteroarylene.

In some embodiments of the present application, 0.1 eV<|HOMO_{EBL}−HOMO_{Host}|≤0.3 eV,
wherein HOMO_{EBL} refers to an energy value of a highest occupied molecular orbital HOMO of a material of the electron blocking layer, and HOMO_{Host} refers to an energy value of a highest occupied molecular orbital HOMO of the host material; and

0.1eV<|LUMO_{HBL}−LUMO_{Host}|≤0.3 eV,
wherein LUMO_{HBL} refers to an energy value of a lowest unoccupied molecular orbital LUMO of a material of the hole blocking layer, and LUMO_{Host} refers to an energy value of a lowest unoccupied molecular orbital LUMO of the host material.

In some embodiments of the present application, T1_{EBL}−T1_{TADF}≥0.1 eV, and S1_{EBL}−S1_{TADF}>0; and

T1_{HBL}−T1_{TADF}>0, and S1_{HBL}−S1_{TADF}>0;
wherein T1_{EBL} refers to an energy value of a first-triplet-state energy level of the material of the electron blocking layer, T1_{TADF} refers to an energy value of a first-triplet-state energy level of the thermally activated delayed-fluorescence material, S1_{EBL} refers to an energy value of a first-singlet-state energy level of the material of the electron blocking layer, and S1_{TADF} refers to an energy value of a first-singlet-state energy level of the thermally activated delayed-fluorescence material; and
T1_{HBL} refers to an energy value of a first-triplet-state energy level of a material of a hole blocking layer, and S1_{HBL} refers to an energy value of a first-singlet-state energy level of the material of the hole blocking layer.
the light emitting device further comprises a hole transporting layer, and the hole transporting layer is located between the electron blocking layer and the first electrode; and

0.1eV<|HOMO_{HTL}−HOMO_{EBL}|≤0.3 eV,
wherein HOMO_{HTL} refers to an energy value of a highest occupied molecular orbital HOMO of a material of the hole transporting layer.

In some embodiments of the present application, the light emitting device further comprises an electron transporting layer, and the electron transporting layer is located between the hole blocking layer and the second electrode; and

0.1eV<|LUMO_{HBL}−LUMO_{ETL}|≤0.3 eV,
wherein LUMO_{ETL} refers to an energy value of a lowest unoccupied molecular orbital LUMO of a material of the electron transporting layer.

In an exemplary embodiment, a thickness of the luminescent layer in a direction perpendicular to a plane where the first electrode is located ranges 15 nm-45 nm;
a thickness of the electron blocking layer in the direction perpendicular to the plane where the first electrode is located ranges 1 nm-15 nm; and
a thickness of the hole blocking layer in the direction perpendicular to the plane where the first electrode is located ranges 1 nm-15 nm.

In the third aspect, an embodiment of the present application provides a displaying device, wherein the displaying device comprises the light emitting device stated above.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the related art, the FIGURES that are required to describe the embodiments or the related art will be briefly described below. Apparently, the FIGURES that are described below are merely embodiments of the present application, and a person skilled in the art can obtain other FIGURES according to these FIGURES without paying creative work.

FIG. 1 is a schematic structural diagram of the light emitting device according to an embodiment of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the drawings, in order for clarity, the thicknesses of the regions and the layers might be exaggerated. In the drawings, the same reference numbers represent the same or similar components, and therefore the detailed description on them are omitted. Moreover, the drawings are merely schematic illustrations of the present application, and are not necessarily drawn to scale.

In the embodiments of the present application, unless stated otherwise, the meaning of “plurality of” is “two or more”. The terms that indicate orientation or position relations, such as “upper”, are based on the orientation or position relations shown in the drawings, and are merely for conveniently describing the present application and simplifying the description, rather than indicating or implying that the component or element must have the specific orientation and be constructed and operated according to the specific orientation. Therefore, they should not be construed as a limitation on the present application.

Unless stated otherwise in the context, throughout the description and the claims, the term “comprise” is interpreted as the meaning of opened containing, i.e., “including but not limited to”. In the description of the present disclosure, the terms “one embodiment”, “some embodiments”, “exemplary embodiments”, “example”, “specific example” or “some examples” are intended to indicate that specific features, structures, materials or characteristics related to the embodiment or example are comprised in at least one embodiment or example of the present application. The illustrative indication of the above terms does not necessarily refer to the same one embodiment or example. Moreover, the specific features, structures, materials or characteristics may be comprised in any one or more embodiments or examples in any suitable manner.

Organic thermally activated delayed fluorescence (TADF) materials have advantages such as a high electroluminescent efficiency and simple molecular design, have already been extensively used as the emitter of organic light emitting diodes (OLED), and have been paid extensive attention in the field of displaying. Because thermally activated delayed-fluorescence molecules can collect triplet excitons to emit light rays and realize the theoretical internal quantum efficiency, they have been considered as one of the most promising materials of organic light emitting diodes. In traditional luminescent materials, usually the lowest singlet state and the lowest triplet state have a large energy-level difference therebetween, and once the excitons have reached the triplet state by an intersystem crossing (ISC) process, they cannot return to the singlet state. However, in thermally activated delayed-fluorescence materials, the excitons can, from a first triplet state T1 (also referred to as an excited triplet state), by a reversed intersystem crossing (RISC) process, reach a first singlet state S1 (also referred to as an excited singlet state), whereby as many excitons as possible can transit from the first singlet state S1 to the ground state S0 and emit light, thereby increasing the luminous efficiency.

However, regarding the organic light emitting diodes having the thermally activated delayed-fluorescence materials, their luminous efficiencies are also influenced by the degree of the matching between the material of the luminescent layer, the material of the electron blocking layer and the material of the hole blocking layer, which causes that their luminous efficiencies and service lives cannot be further increased.

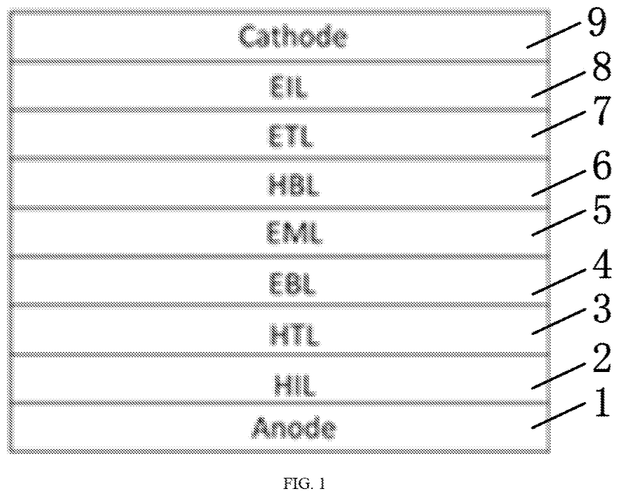

An embodiment of the present application provides a light emitting device. Referring to FIG. 1, the light emitting device comprises:
a first electrode 1 and a second electrode 9;
a luminescent layer 5, located between the first electrode 1 and the second electrode 9, comprising a host material Host and a thermally activated delayed-fluorescence material (TADF); and
an electron blocking layer 4, located between the luminescent layer 5 and the first electrode 1; and

0.1 eV<|HOMO_{EBL}−HOMO_{Host}|≤0.3 eV,
wherein HOMO_{EBL} refers to the energy value of the highest occupied molecular orbital HOMO of the material of the electron blocking layer 4, and HOMO_{Host} refers to the energy value of the highest occupied molecular orbital HOMO of the host material Host.

In an exemplary embodiment, the first electrode 1 may be the anode, and the second electrode 9 may be the cathode.

The quantity of the luminescent layer comprised in the light emitting device is not limited herein.

As an example, the light emitting device may comprise a plurality of luminescent layers, all of the plurality of luminescent layers are located between the first electrode 1 and the second electrode 9, and the plurality of luminescent layers are arranged in stack, to increase the luminous efficiency. The embodiments of the present application define the material of at least one of the plurality of luminescent layers. It can be understood that, if the light emitting device comprises a plurality of luminescent layers, at least one of the luminescent layers comprises the host material Host and the thermally activated delayed-fluorescence material TADF.

As an example, the light emitting device comprises one luminescent layer, and the luminescent layer comprises the host material Host and the thermally activated delayed-fluorescence material TADF.

It should be noted that the embodiments of the present application illustrate by taking the case as an example in which the light emitting device comprises one luminescent layer 5.

The emitted-light color of the luminescent layer 5 is not limited herein. As an example, the emitted-light color of the luminescent layer 5 may be the red color. Alternatively, the emitted-light color of the luminescent layer 5 may be the green color. Alternatively, the emitted-light color of the luminescent layer 5 may be the blue color.

In an exemplary embodiment, the luminescent layer 5 may comprise at least one host material.

For example, the luminescent layer 5 comprises one host material.

As another example, the luminescent layer 5 comprises two host materials. As an example, one of them is an N-type host material, and the other is a P-type host material.

The particular structure of the host material is not limited herein, and may be particularly determined according to practical situations.

The thermally activated delayed fluorescence is a process in which triplet excitons are thermally activated and subsequently emit light. In other words, the triplet excitons are thermally activated and then converted into their higher vibration energy level, subsequently reach the vibration energy level of the singlet state close to its energy level by reversed intersystem crossing, and subsequently radiate to generate fluorescence, wherein the fluorescence is delayed as compared with the direct light emission of the singlet state, and is referred to as delayed fluorescence. In order to ensure a high-efficiency reversed intersystem crossing (RISC), usually, thermally activated delayed-fluorescence materials have a low energy gap between the triplet state and the singlet state.

The energy level of the highest occupied molecular orbital (HOMO) reflects the magnitude of the capacity of a molecule of losing an electron, wherein if the energy value of the HOMO energy level is higher, the substance is more easy to lose an electron, whereby a hole is transferred. The energy level of the lowest unoccupied molecular orbital (LUMO) reflects the magnitude of the capacity of a molecule of obtaining an electron, wherein if the energy value of the LUMO energy level is lower, the substance is more easy to obtain an electron, whereby an electron is transferred.

The electron blocking layer 4 has the function of facilitating hole injection and restricting electron leakage. The particular structure of the electron blocking layer is not limited herein.

In the embodiments of the present application, by configuring that the absolute value of the difference between the energy value of the highest occupied molecular orbital HOMO of the material of the electron blocking layer 4 and the energy value of the highest occupied molecular orbital HOMO of the host material Host is greater than 0.1 eV and less than or equal to 0.3 eV, the degree of the matching between the host material of the luminescent layer and the material of the electron blocking layer is increased, to facilitate the holes to be transmitted from the electron blocking layer and injected into the luminescent layer, whereby as many holes as possible are injected into the host material of the luminescent layer and recombine with the electrons in the luminescent layer to form excitons, and the excitons have radioluminescence, thereby increasing the luminous efficiency of the light emitting device. Additionally, the electron blocking layer can, to a large extent, prevent the electrons from leaking from the luminescent layer to the side of the electron blocking layer that is closer to the first electrode 1, which increases the service life of the light emitting device to a large extent.

In some embodiments of the present application, referring to FIG. 1, the light emitting device further comprises a hole blocking layer 6, and the hole blocking layer 6 is located between the luminescent layer 5 and the second electrode 9; and

0.1eV<|LUMO_{HBL}−LUMO_{Host}|≤0.3 eV,
wherein LUMO_{HBL} refers to the energy value of the lowest unoccupied molecular orbital LUMO of the material of the hole blocking layer 6, and LUMO_{Host} refers to the energy value of the lowest unoccupied molecular orbital LUMO of the host material.

In the embodiments of the present application, by configuring that the absolute value of the difference between the energy value of the highest occupied molecular orbital HOMO of the material of the electron blocking layer 4 and the energy value of the highest occupied molecular orbital HOMO of the host material Host is greater than 0.1 eV and less than or equal to 0.3 eV, and further configuring that the absolute value of the difference between the energy value of the lowest unoccupied molecular orbital LUMO of the material of the hole blocking layer 6 and the energy value of the lowest unoccupied molecular orbital LUMO of the host material is greater than 0.1 eV and less than or equal to 0.3 eV, the degree of the matching between the host material of the luminescent layer 5 and the material of the electron blocking layer 4 is increased, and the degree of the matching between the host material of the luminescent layer 5 and the material of the hole blocking layer 6 is also increased, whereby as many holes and electrons as possible are injected into the host material of the luminescent layer and reach balance in the luminescent layer, thereby preventing the electrons or the holes from leaking from the luminescent layer. Accordingly, in an aspect, the service life of the light emitting device can be increased, and, in another aspect, the holes and the electrons recombine in the luminescent layer to form excitons, and the excitons have radioluminescence, which increases the utilization ratio of the recombination between the holes and the electrons to form the excitons, thereby increasing the luminous efficiency of the light emitting device.

In some embodiments of the present application, T1_{EBL}−T1_{TADF}≥0.1 eV, and S1_{EBL}−S1_{TADF}>0,
wherein T1_{EBL} refers to the energy value of the first-triplet-state energy level of the material of the electron blocking layer, T1_{TADF} refers to the energy value of the first-triplet-state energy level of the thermally activated delayed-fluorescence material, S1_{EBL} refers to the energy value of the first-singlet-state energy level of the material of the electron blocking layer, and S1_{TADF} refers to the energy value of the first-singlet-state energy level of the thermally activated delayed-fluorescence material.

In the embodiments of the present application, as compared with the thermally activated delayed-fluorescence material, the electron blocking layer that has a higher energy value T1_{EBL} of the first-triplet-state energy level and a higher energy value S1_{EBL} of the first-singlet-state energy level facilitates to prevent electron leakage, and can prevent the excitons in the thermally activated delayed-fluorescence material from leaking into the electron blocking layer, thereby facilitating to increase the luminous efficiency of the luminescent layer.

In some embodiments of the present application, T1_{HBL}−T1_{TADF}>0, and S1_{HBL}−S1_{TADF}>0,
wherein T1_{HBL} refers to the energy value of the first-triplet-state energy level of the material of the hole blocking layer, and S1_{HBL} refers to the energy value of the first-singlet-state energy level of the material of the hole blocking layer.

In the embodiments of the present application, as compared with the thermally activated delayed-fluorescence material, the hole blocking layer that has a higher energy value T1_{HBL} of the first-triplet-state energy level and a higher energy value S1_{HBL} of the first-singlet-state energy level facilitates to prevent hole leakage, and can prevent the excitons in the thermally activated delayed-fluorescence material from leaking into the hole blocking layer, thereby facilitating to increase the luminous efficiency of the luminescent layer.

It should be noted that, in the embodiments of the present application, the magnitude relation between the energy value T1_{Host} of the first-triplet-state energy level of the host material of the luminescent layer and the energy value T1_{TADF} of the first-triplet-state energy level of the thermally activated delayed-fluorescence material of the luminescent layer is not limited, and may be particularly determined according to the type of the host material and the type of the thermally activated delayed-fluorescence material in practical applications. That may be particularly determined according to the material design of the luminescent layer.

In some embodiments, T1_{Host}-T1_{TADF}>0. In some other embodiments, T1_{Host}−T1_{TADF}<0.

In some embodiments of the present application, the material of the electron blocking layer, the host material and the material of the hole blocking layer individually comprise:

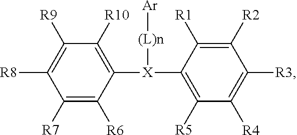

wherein X comprises one of a boron atom, a carbon atom, a nitrogen atom, an oxygen atom, a silicon atom, a phosphorus atom and a sulphur atom, L comprises one of substituted or unsubstituted C6-C20 arylene and substituted or unsubstituted C3-C30 heteroarylene, and n is one of 0, 1 and 2.

In some embodiments of the present application, R1-R10 individually comprise one of hydrogen, C-C12 alkyl, substituted or unsubstituted C6-C30 arylene and substituted or unsubstituted C3-C30 heteroarylene.

In some embodiments of the present application, at least one pair of two neighboring groups among R1-R10 are connected to form a ring.

As an example, that at least one pair of two neighboring groups among R1-R10 are connected to form a ring includes but is not limited to the following cases:

R1 and R2 may be connected to form a ring; or R2 and R3 may be connected to form a ring; or R3 and R4 may be connected to form a ring; or R4 and R5 may be connected to form a ring; or R1 and R2 may be connected to form a ring, and R3 and R4 may be connected to form a ring; or R6 and R7 may be connected to form a ring; or R7 and R8 may be connected to form a ring; or R8 and R9 may be connected to form a ring; or R9 and R10 may be connected to form a ring; or R6 and R7 may be connected to form a ring, and R8 and R9 may be connected to form a ring.

In some embodiments of the present application, Ar comprises one of hydrogen, C1-C12 alkyl, substituted or unsubstituted C6-C30 arylene and substituted or unsubstituted C3-C30 heteroarylene.

In the embodiments of the present application, because the energy levels of the material of the electron blocking layer, the host material and the material of the hole blocking layer are different, although all of the materials of them may comprise the above general structural formulas, in practical situations, the structures of the materials of them are not completely the same.

In an exemplary embodiment, if n=0,

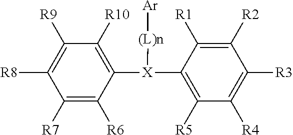

includes but is not limited to the following structures:

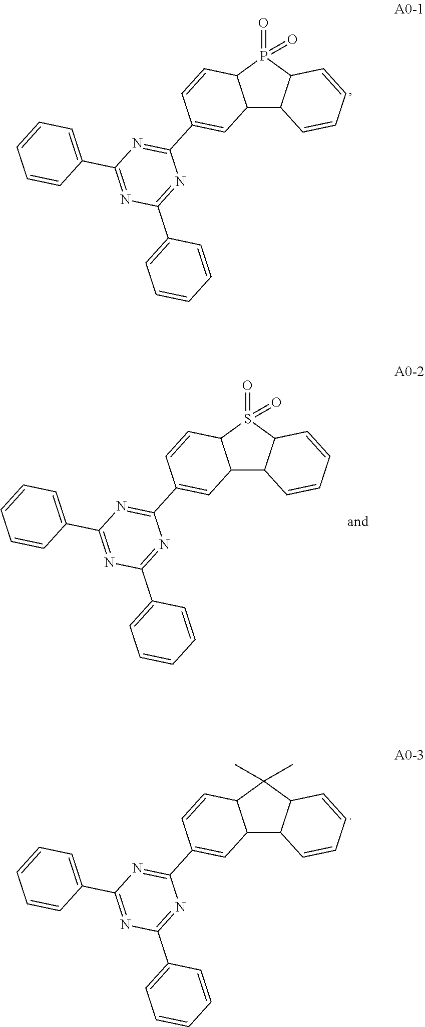

In an exemplary embodiment, if n=1,

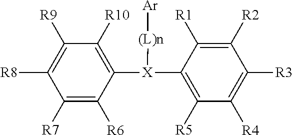

includes but is not limited to the following structures:

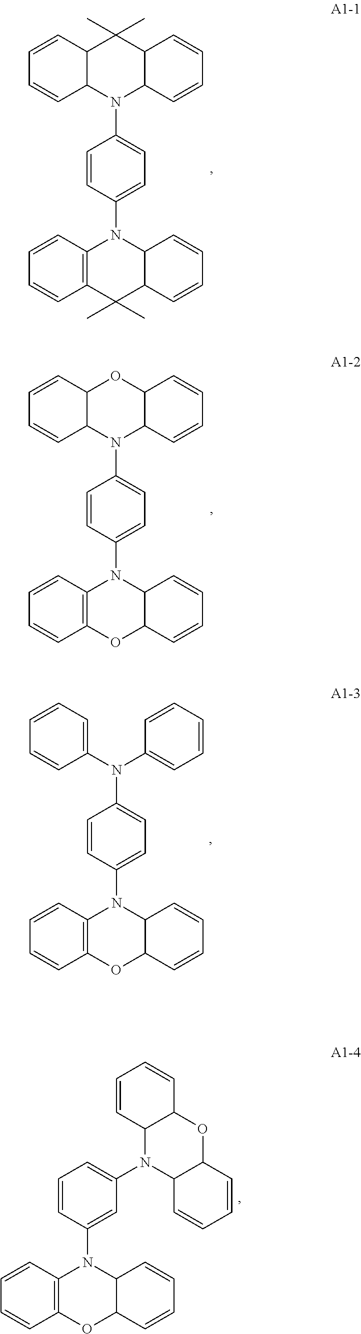 [SMILES: CC1(C)c2ccccc2N(c2ccc(N3C4C=CC=CC4C(C)(C)C4C=CC=CC43)cc2)C2C=CC=CC21 ; C1=CC2Oc3ccccc3N(c3ccc(N4C5C=CC=CC5OC5C=CC=CC54)cc3)C2C=C1 ; C1=CC2Oc3ccccc3N(c3ccc(N(c4ccccc4)c4ccccc4)cc3)C2C=C1 ; C1=CC2Oc3ccccc3N(c3cccc(N4C5C=CC=CC5OC5C=CC=CC54)c3)C2C=C1]

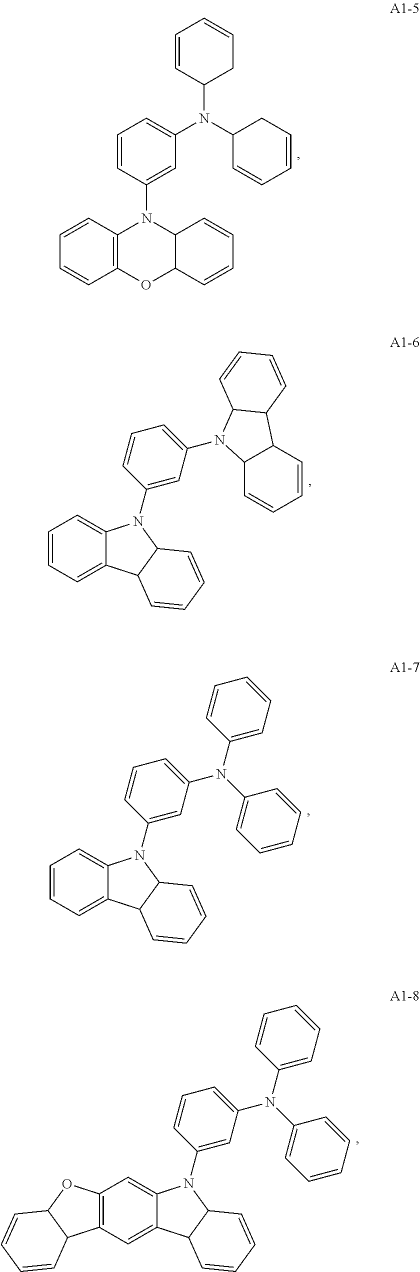 [SMILES: C1=CCC(N(c2cccc(N3c4ccccc4OC4C=CC=CC43)c2)C2C=CC=CC2)C=C1 ; C1=CC2c3ccccc3N(c3cccc(N4C5C=CC=CC5C5C=CC=CC54)c3)C2C=C1 ; C1=CC2c3ccccc3N(c3cccc(N(c4ccccc4)c4ccccc4)c3)C2C=C1 ; C1=CC2Oc3cc4c(cc3C2C=C1)C1C=CC=CC1N4c1cccc(N(c2ccccc2)c2ccccc2)c1]

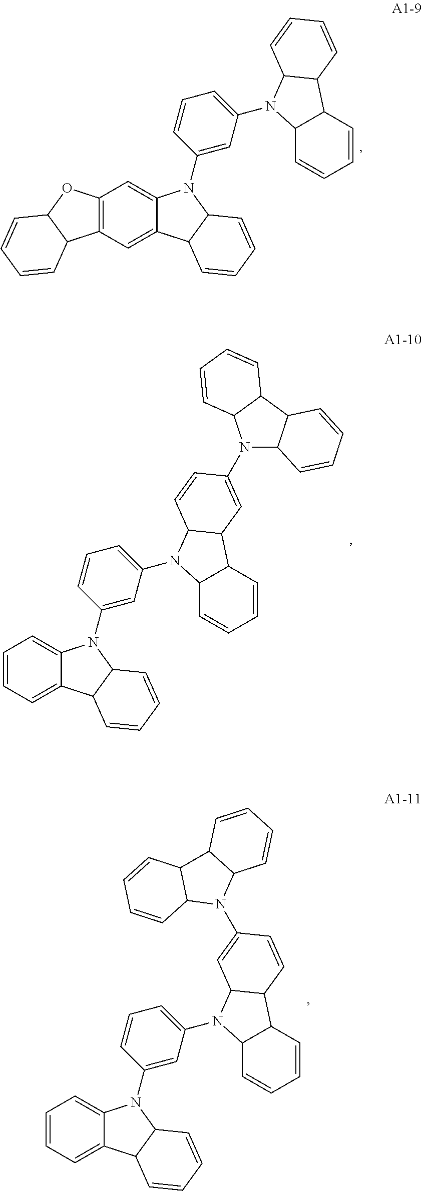 [SMILES: C1=CC2Oc3cc4c(cc3C2C=C1)C1C=CC=CC1N4c1cccc(N2C3C=CC=CC3C3C=CC=CC32)c1 ; C1=CC2c3ccccc3N(c3cccc(N4C5C=CC=CC5C5C=C(N6C7C=CC=CC7C7C=CC=CC76)C=CC54)c3)C2C=C1 ; C1=CC2c3ccccc3N(c3cccc(N4C5C=CC=CC5C5C=CC(N6C7C=CC=CC7C7C=CC=CC76)=CC54)c3)C2C=C1]

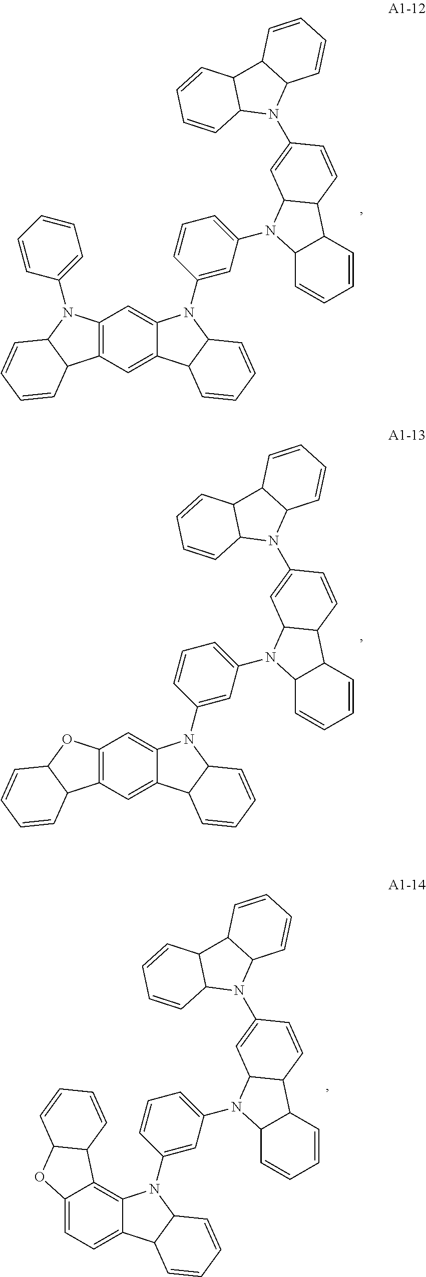 [SMILES: C1=CC2c3cc4c(cc3N(c3ccccc3)C2C=C1)N(c1cccc(N2C3C=CC=CC3C3C=CC(N5C6C=CC=CC6C6C=CC=CC65)=CC32)c1)C1C=CC=CC41 ; C1=CC2Oc3cc4c(cc3C2C=C1)C1C=CC=CC1N4c1cccc(N2C3C=CC=CC3C3C=CC(N4C5C=CC=CC5C5C=CC=CC54)=CC32)c1 ; C1=CC2Oc3ccc4c(c3C2C=C1)N(c1cccc(N2C3C=CC=CC3C3C=CC(N5C6C=CC=CC6C6C=CC=CC65)=CC32)c1)C1C=CC=CC41]

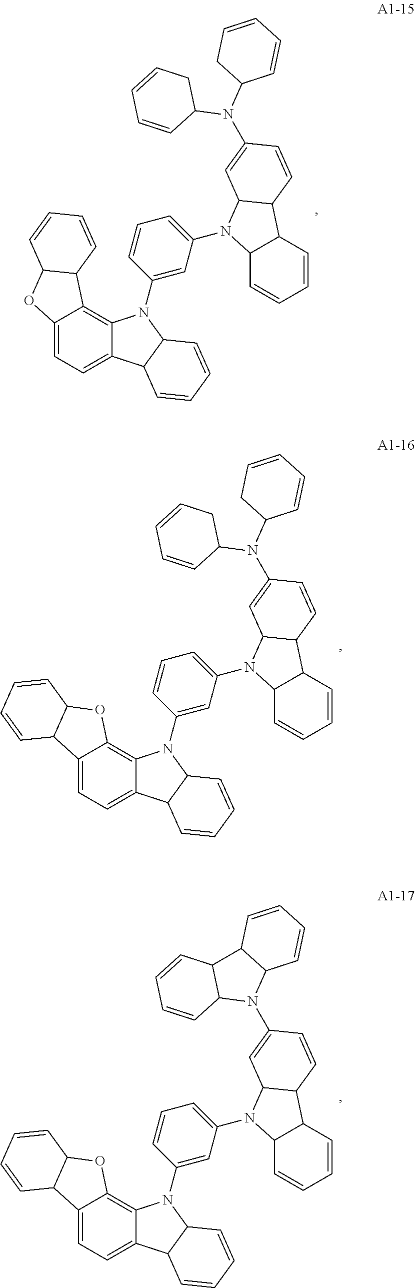 [SMILES: C1=CCC(N(C2=CC3C(C=C2)C2C=CC=CC2N3c2cccc(N3c4c(ccc5c4C4C=CC=CC4O5)C4C=CC=CC43)c2)C2C=CC=CC2)C=C1 ; C1=CCC(N(C2=CC3C(C=C2)C2C=CC=CC2N3c2cccc(N3c4c(ccc5c4OC4C=CC=CC54)C4C=CC=CC43)c2)C2C=CC=CC2)C=C1 ; C1=CC2Oc3c(ccc4c3N(c3cccc(N5C6C=CC=CC6C6C=CC(N7C8C=CC=CC8C8C=CC=CC87)=CC65)c3)C3C=CC=CC43)C2C=C1]

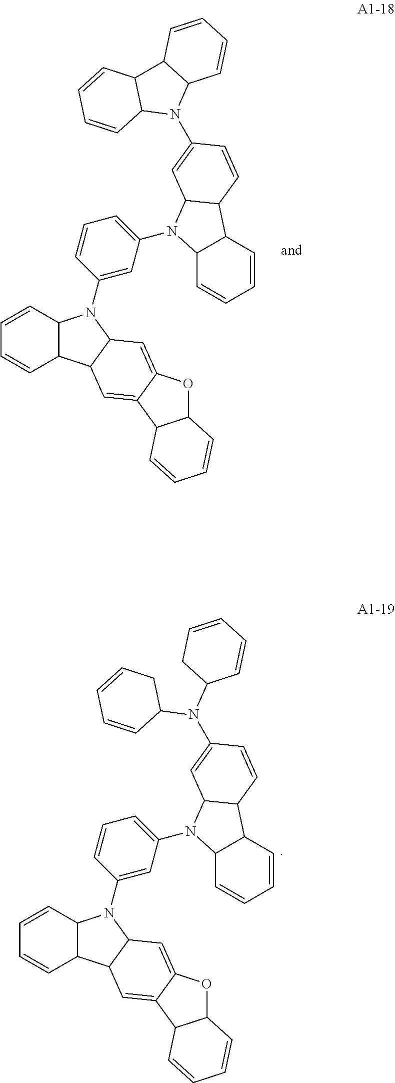 [SMILES: C1=CC2OC3=CC4C(C=C3C2C=C1)C1C=CC=CC1N4c1cccc(N2C3C=CC=CC3C3C=CC(N4C5C=CC=CC5C5C=CC=CC54)=CC32)c1 ; C1=CCC(N(C2=CC3C(C=C2)C2C=CC=CC2N3c2cccc(N3C4C=CC=CC4C4C=C5C(=CC43)OC3C=CC=CC53)c2)C2C=CC=CC2)C=C1]

In an exemplary embodiment, if n=2,

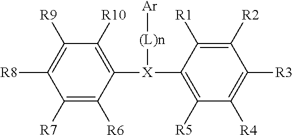

includes but is not limited to the following structures:

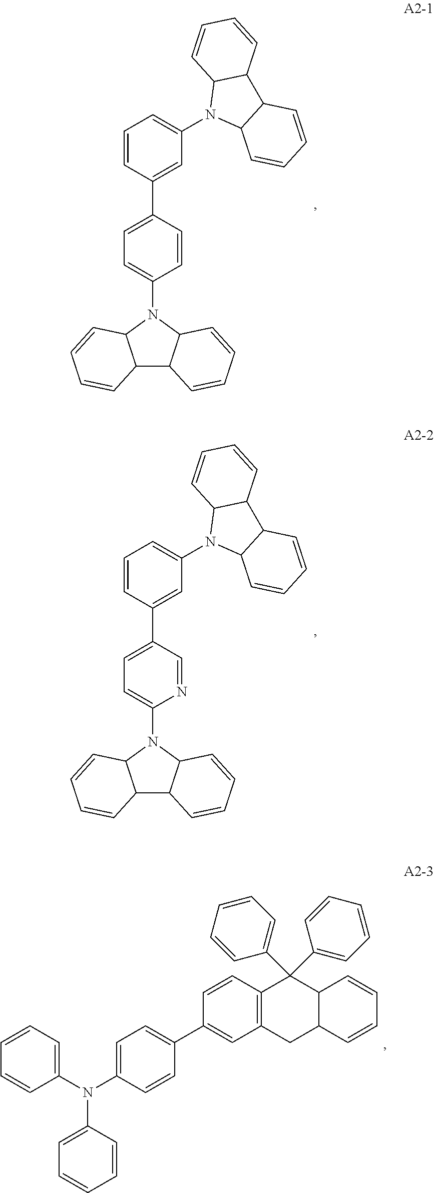 [SMILES: C1=CC2C3C=CC=CC3N(c3ccc(-c4cccc(N5C6C=CC=CC6C6C=CC=CC65)c4)cc3)C2C=C1 ; C1=CC2C3C=CC=CC3N(c3cccc(-c4ccc(N5C6C=CC=CC6C6C=CC=CC65)nc4)c3)C2C=C1 ; C1=CC2Cc3cc(-c4ccc(N(c5ccccc5)c5ccccc5)cc4)ccc3C(c3ccccc3)(c3ccccc3)C2C=C1]

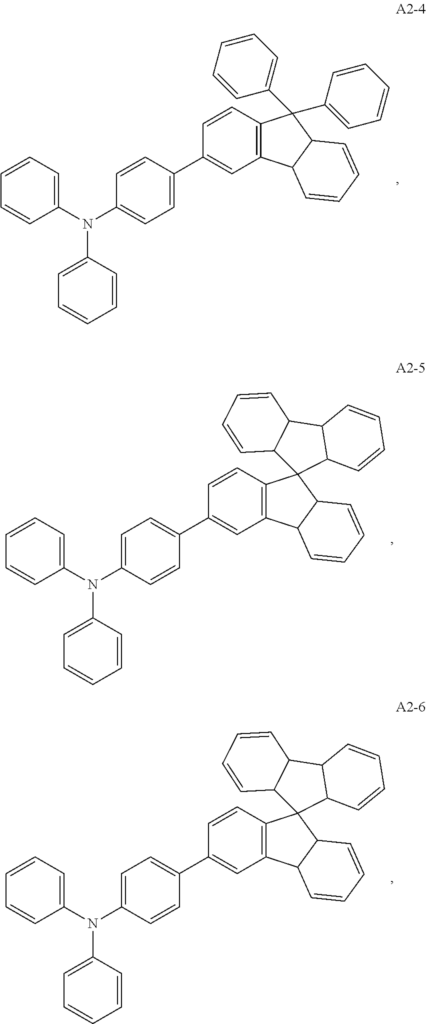 [SMILES: C1=CC2c3cc(-c4ccc(N(c5ccccc5)c5ccccc5)cc4)ccc3C(c3ccccc3)(c3ccccc3)C2C=C1 ; C1=CC2c3cc(-c4ccc(N(c5ccccc5)c5ccccc5)cc4)ccc3C3(C2C=C1)C1C=CC=CC1C1C=CC=CC13 ; C1=CC2c3cc(-c4ccc(N(c5ccccc5)c5ccccc5)cc4)ccc3C3(C2C=C1)C1C=CC=CC1C1C=CC=CC13]

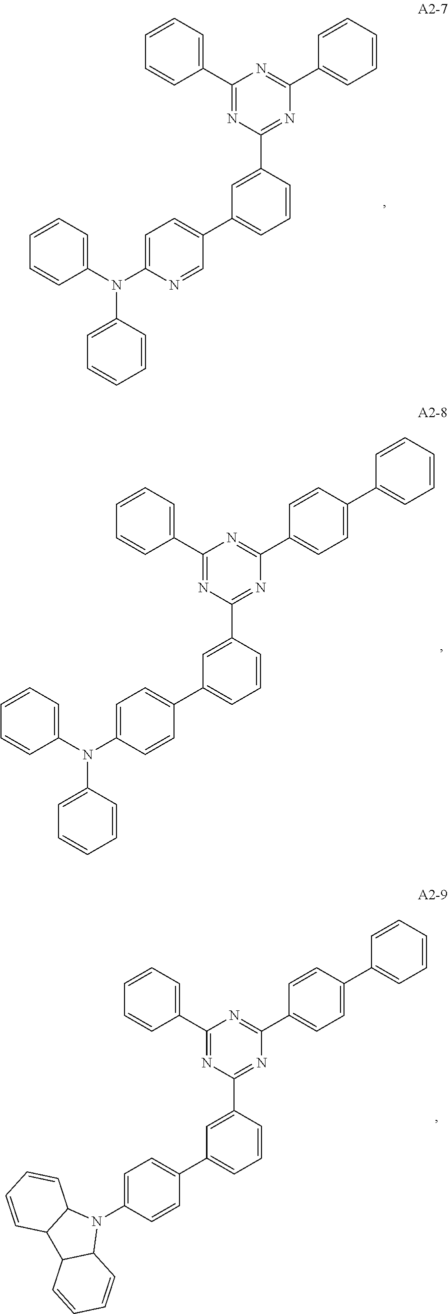 [SMILES: c1ccc(-c2nc(-c3ccccc3)nc(-c3cccc(-c4ccc(N(c5ccccc5)c5ccccc5)nc4)c3)n2)cc1 ; c1ccc(-c2ccc(-c3nc(-c4ccccc4)nc(-c4cccc(-c5ccc(N(c6ccccc6)c6ccccc6)cc5)c4)n3)cc2)cc1 ; C1=CC2C3C=CC=CC3N(c3ccc(-c4cccc(-c5nc(-c6ccccc6)nc(-c6ccc(-c7ccccc7)cc6)n5)c4)cc3)C2C=C1]

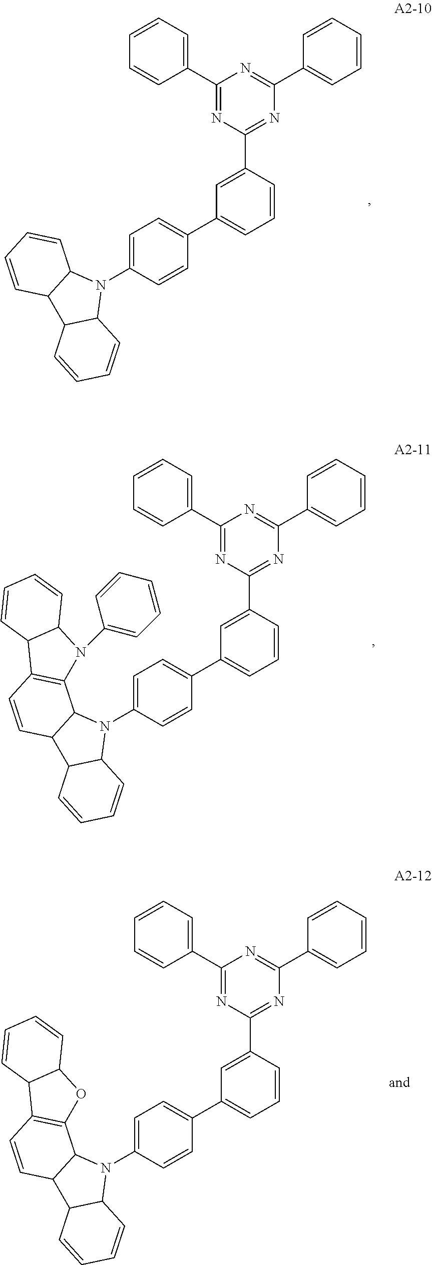 [SMILES: C1=CC2C3C=CC=CC3N(c3ccc(-c4cccc(-c5nc(-c6ccccc6)nc(-c6ccccc6)n5)c4)cc3)C2C=C1 ; C1=CC2C3=C(C4C(C=C3)C3C=CC=CC3N4c3ccc(-c4cccc(-c5nc(-c6ccccc6)nc(-c6ccccc6)n5)c4)cc3)N(c3ccccc3)C2C=C1 ; C1=CC2OC3=C(C=CC4C5C=CC=CC5N(c5ccc(-c6cccc(-c7nc(-c8ccccc8)nc(-c8ccccc8)n7)c6)cc5)C34)C2C=C1]

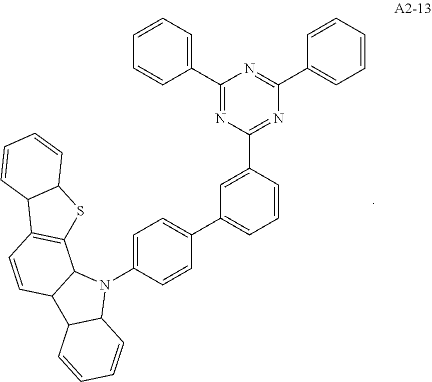 [SMILES: C1=CC2SC3=C(C=CC4C5C=CC=CC5N(c5ccc(-c6cccc(-c7nc(-c8ccccc8)nc(-c8ccccc8)n7)c6)cc5)C34)C2C=C1]

In some embodiments of the present application, the material of the hole blocking layer comprises:

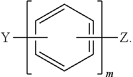

In some embodiments of the present application, the glass-transition temperature of the material of the hole blocking layer is greater than or equal to 85° C.

In some embodiments of the present application, Y and Z individually comprise hydrogen, diplogen, halogen group, nitrile group, nitro, hydroxyl, carbonyl, ester group, imide group, amino, substituted or unsubstituted C3-C30 silyl, substituted or unsubstituted boryl, substituted or unsubstituted C1-C30 alkyl, substituted or unsubstituted C3-C30 cycloalkyl, substituted or unsubstituted alkoxy, substituted or unsubstituted aryloxy, substituted or unsubstituted alkylsulfenyl, substituted or unsubstituted arylsulfenyl, substituted or unsubstituted alkylsulfonyl, substituted or unsubstituted C6-C30 arylsulfonyl, substituted or unsubstituted alkenyl, substituted or unsubstituted aralkyl, substituted or unsubstituted aralkenyl, substituted or unsubstituted alkaryl, substituted or unsubstituted alkylamido, substituted or unsubstituted C1-C30 aralkylamido, substituted or unsubstituted C6-C30 heteroarylamido, substituted or unsubstituted C6-C30 arylamido, substituted or unsubstituted C6-C30 arylheteroarylamido, substituted or unsubstituted C6-C30 arylphosphino, substituted or unsubstituted phosphine oxide group, substituted or unsubstituted C6-C30 aryl, substituted or unsubstituted heterocyclic group, substituted or unsubstituted C1-C30 alkyl C6-C30 diarylsilyl, and substituted or unsubstituted C3-C30 monocyclic or polycyclic alicyclic ring or aromatic ring.

The substituted or unsubstituted C1-C30 alkyl C6-C30 diarylsilyl comprises: substituted or unsubstituted alkyldiarylsilyl, wherein the quantity of the carbon atoms of the alkyl is 1-30, and the quantity of the carbon atoms of the diaryl is 6-30.

The substituted or unsubstituted C3-C30 monocyclic or polycyclic alicyclic ring or aromatic ring comprises: substituted or unsubstituted C3-C30 monocyclic alicyclic ring, substituted or unsubstituted C3-C30 monocyclic aromatic ring, substituted or unsubstituted C3-C30 polycyclic alicyclic ring, and substituted or unsubstituted C3-C30 polycyclic aromatic ring.

In some embodiments of the present application, if at least one of X and Y comprises the substituted or unsubstituted C3-C30 monocyclic or polycyclic alicyclic ring or aromatic ring, the alicyclic ring or aromatic ring comprises at least one heteroatom, and the heteroatom comprises oxygen atom, sulphur atom or nitrogen atom.

M is greater than or equal to 3.

In the embodiments of the present application, when m is greater than or equal to 3, the molecule has a good conjugation property, whereby the above structures have a good physicochemical stability and a good property of blocking holes, can effectively block hole leakage, and can increase the service life of the light emitting device to a large extent.

In an exemplary embodiment, if m=3,

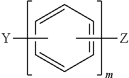

includes but is not limited to the following structures:

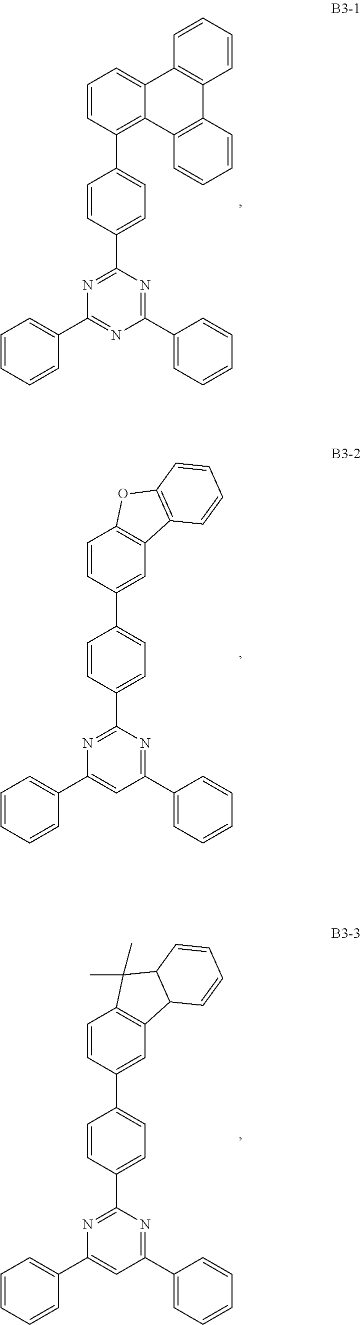 [SMILES: c1ccc(-c2nc(-c3ccccc3)nc(-c3ccc(-c4cccc5c6ccccc6c6ccccc6c45)cc3)n2)cc1 ; c1ccc(-c2cc(-c3ccccc3)nc(-c3ccc(-c4ccc5oc6ccccc6c5c4)cc3)n2)cc1 ; CC1(C)c2ccc(-c3ccc(-c4nc(-c5ccccc5)cc(-c5ccccc5)n4)cc3)cc2C2C=CC=CC21]

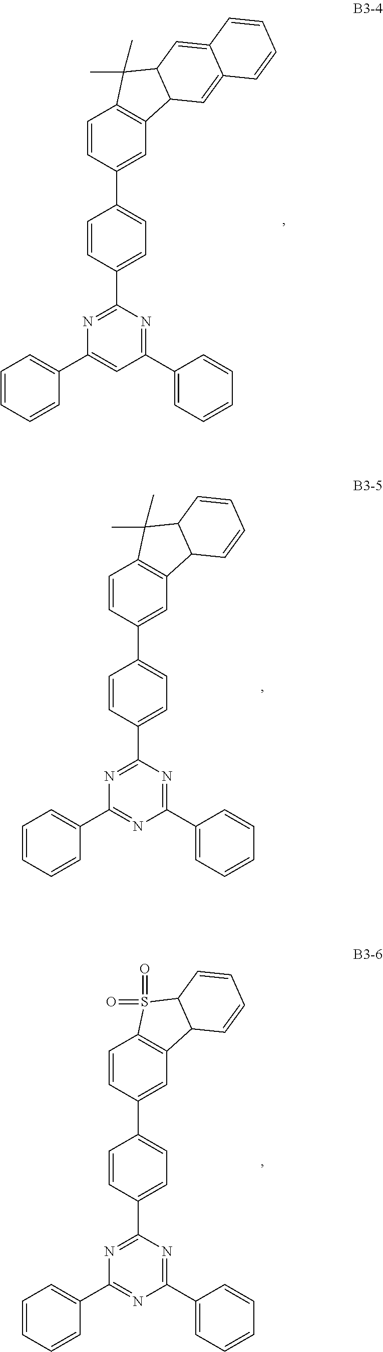 [SMILES: CC1(C)c2ccc(-c3ccc(-c4nc(-c5ccccc5)cc(-c5ccccc5)n4)cc3)cc2C2C=c3ccccc3=CC21 ; CC1(C)c2ccc(-c3ccc(-c4nc(-c5ccccc5)nc(-c5ccccc5)n4)cc3)cc2C2C=CC=CC21 ; O=S1(=O)c2ccc(-c3ccc(-c4nc(-c5ccccc5)nc(-c5ccccc5)n4)cc3)cc2C2C=CC=CC21]

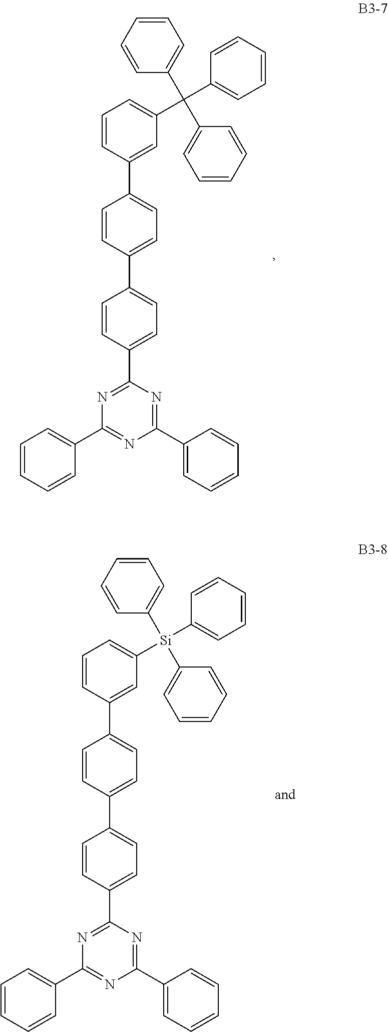 [SMILES: c1ccc(-c2nc(-c3ccccc3)nc(-c3ccc(-c4ccc(-c5cccc(C(c6ccccc6)(c6ccccc6)c6ccccc6)c5)cc4)cc3)n2)cc1 ; c1ccc(-c2nc(-c3ccccc3)nc(-c3ccc(-c4ccc(-c5cccc([Si](c6ccccc6)(c6ccccc6)c6ccccc6)c5)cc4)cc3)n2)cc1]

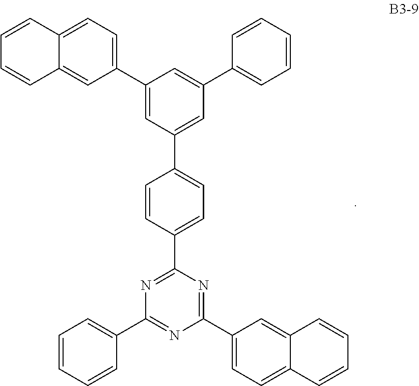 [SMILES: c1ccc(-c2cc(-c3ccc(-c4nc(-c5ccccc5)nc(-c5ccc6ccccc6c5)n4)cc3)cc(-c3ccc4ccccc4c3)c2)cc1]

In an exemplary embodiment, if m=4,

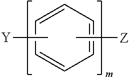

includes but is not limited to the following structures:

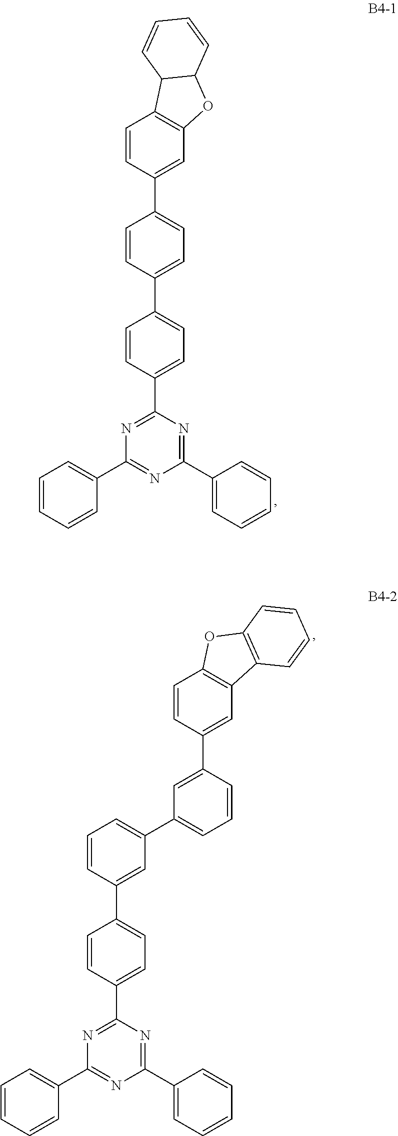 [SMILES: C1=CC2Oc3cc(-c4ccc(-c5ccc(-c6nc(-c7ccccc7)nc(-c7ccccc7)n6)cc5)cc4)ccc3C2C=C1 ; c1ccc(-c2nc(-c3ccccc3)nc(-c3ccc(-c4cccc(-c5cccc(-c6ccc7oc8ccccc8c7c6)c5)c4)cc3)n2)cc1]

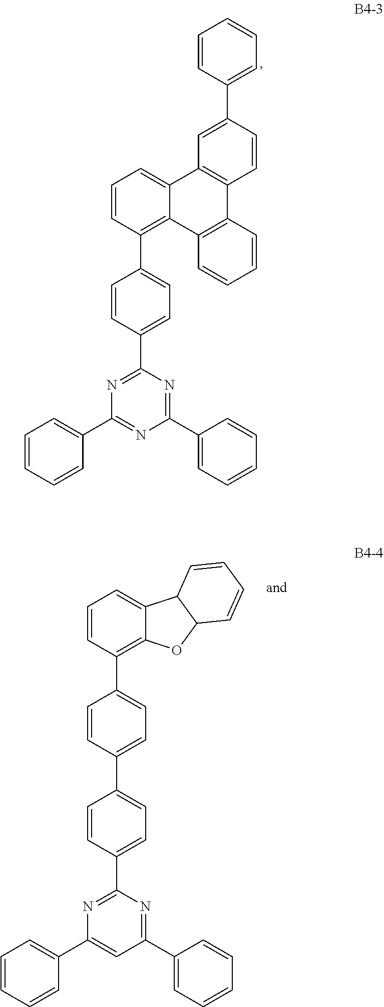 [SMILES: c1ccc(-c2ccc3c4ccccc4c4c(-c5ccc(-c6nc(-c7ccccc7)nc(-c7ccccc7)n6)cc5)cccc4c3c2)cc1 ; C1=CC2Oc3c(-c4ccc(-c5ccc(-c6nc(-c7ccccc7)cc(-c7ccccc7)n6)cc5)cc4)cccc3C2C=C1]

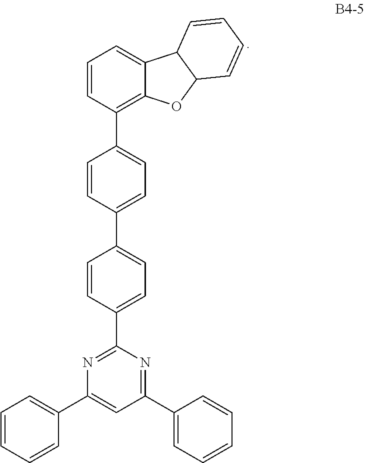 [SMILES: C1=CC2Oc3c(-c4ccc(-c5ccc(-c6nc(-c7ccccc7)cc(-c7ccccc7)n6)cc5)cc4)cccc3C2C=C1]

In some embodiments of the present application, referring to FIG. 1, the light emitting device further comprises a hole transporting layer 3, and the hole transporting layer 3 is located between the electron blocking layer 4 and the first electrode 1; and

0.1eV<|HOMO_{HTL}−HOMO_{EBL}|≤0.3 eV,
wherein HOMO_{HTL} refers to the energy value of the highest occupied molecular orbital HOMO of the material of the hole transporting layer 4.

In the embodiments of the present application, by configuring that the absolute value of the difference between the energy value HOMO_{HTL} of the highest occupied molecular orbital HOMO of the material of the hole transporting layer 3 and the energy value HOMO_{EBL} of the highest occupied molecular orbital HOMO of the material of the electron blocking layer 4 is greater than 0.1 eV and less than or equal to 0.3 eV, the degree of the matching between the HOMO energy levels of the material of the hole transporting layer 3 and the material of the electron blocking layer 4 is increased, whereby the holes can, from the hole transporting layer 3, pass through the electron blocking layer 4 and be injected into the luminescent layer 5 with a high efficiency, which can increase the luminous efficiency of the light emitting device while increasing the lives of the film layers of the light emitting device.

In some embodiments of the present application, referring to FIG. 1, the light emitting device further comprises an electron transporting layer 7, and the electron transporting layer 7 is located between the hole blocking layer 6 and the second electrode 9; and
0.1 eV<|LUMO_{HBL}−LUMO_{ETL}|≤0.3 eV, wherein LUMO_{ETL} refers to the energy value of the lowest unoccupied molecular orbital LUMO of the material of the electron transporting layer 7.

In the embodiments of the present application, by configuring that the absolute value of the difference between the energy value LUMO_{HBL} of the lowest unoccupied molecular orbital LUMO of the material of the hole blocking layer 6 and the energy value LUMO_{ETL} of the lowest unoccupied molecular orbital LUMO of the material of the electron transporting layer 7 is greater than 0.1 eV and less than or equal to 0.3 eV, the degree of the matching between the LUMO energy levels of the material of the hole blocking layer 6 and the material of the electron transporting layer 7 is increased, whereby the electrons can, from the electron transporting layer 7, pass through the hole blocking layer 6 and be injected into the luminescent layer 5 with a high efficiency, which can increase the luminous efficiency of the light emitting device while increasing the lives of the film layers of the light emitting device.

In some embodiments of the present application, T1_{Host}≥2.45 eV, T1_{EBL}≥2.55 eV, and S1_{EBL}≥2.90 eV.

In the embodiments of the present application, by configuring that T1_{Host}≥2.45 eV, the host material has a higher energy value of the first-triplet-state energy level, which facilitates to constraint the excitons inside the thermally activated delayed-fluorescence material, to increase the luminous efficiency of the delayed fluorescence, thereby increasing the luminous efficiency of the light emitting device.

In the embodiments of the present application, by configuring that T1_{EBL}≥2.55 eV, and S1_{EBL}≥2.90 eV, the electron blocking layer that has a higher energy value T1_{EBL} of the first-triplet-state energy level and a higher energy value S1_{EBL} of the first-singlet-state energy level facilitates to prevent electron leakage, and can prevent the excitons in the thermally activated delayed-fluorescence material from leaking into the electron blocking layer, thereby facilitating to increase the luminous efficiency of the luminescent layer.

In some embodiments of the present application, S1_{HBL}≥3.00 eV, and T1_{HBL≥}2.60 eV.

By configuring that S1_{HBL}≥3.00 eV, and T1_{HBL}≥2.60 eV, the hole blocking layer that has a higher energy value T1_{HBL} of the first-triplet-state energy level and a higher energy value S1_{HBL} of the first-singlet-state energy level facilitates to prevent hole leakage, and can prevent the excitons in the thermally activated delayed-fluorescence material from leaking into the hole blocking layer, thereby facilitating to increase the luminous efficiency of the luminescent layer.

In some embodiments of the present application, |HOMO_{EBL}|≥5.6 eV, and |HOMO_{Host}|≥5.8 eV.

The energy level of the highest occupied molecular orbital (HOMO) reflects the magnitude of the capacity of a molecule of losing an electron, wherein if the energy value of the HOMO energy level is higher, the substance is more easy to lose an electron, whereby a hole is transferred. By configuring that |HOMO_{EBL}|≥5.6 eV, and |HOMO_{Host}|≥5.8 eV, the degree of the matching between the host material of the luminescent layer and the material of the electron blocking layer is increased, to facilitate the holes to be transmitted from the electron blocking layer and injected into the luminescent layer, whereby as many holes as possible are injected into the host material of the luminescent layer and recombine with the electrons in the luminescent layer to form excitons, and the excitons have radioluminescence, thereby increasing the luminous efficiency of the light emitting device. Additionally, the electron blocking layer can, to a large extent, prevent the electrons from leaking from the luminescent layer to the side of the electron blocking layer that is closer to the first electrode 1, which increases the service life of the light emitting device to a large extent.

In an exemplary embodiment, referring to FIG. 1, the light emitting device may further comprise a hole injection layer 2 and an electron injection layer 8. Certainly, the light emitting device may further comprise other film layers and components, which may particularly refer to the related art, and is not limited herein.

The methods for fabricating three types of the light emitting device according to the present application and the methods for fabricating two types of the light emitting device in the related art, and the relevant test data, will be provided below, to demonstrate that the luminous efficiency and the service life of the light emitting device according to the embodiments of the present application have been effectively increased.

The method for fabricating the first type of the light emitting device according to the embodiments of the present application is as follows:
S01: forming an anode Anode on a glass substrate by vacuum vapor deposition, wherein the thickness of the anode may be 100 nm, and the material of the anode is indium tin oxide (ITO).
S02: depositing a hole-injection material on the anode by vacuum vapor deposition, to form a hole injection layer HIL.

As an example, the thickness of the hole injection layer may be 10 nm.
S03: forming a hole transporting layer HTL on the hole injection layer.

As an example, the thickness of the hole transporting layer may be 60 nm.
S04: forming an electron blocking layer EBL on the hole transporting layer.

The material of the electron blocking layer comprises

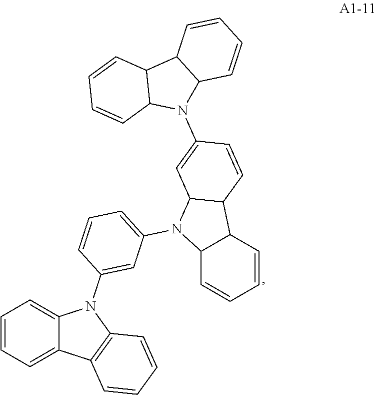 [SMILES: C1=CC2C3C=CC=CC3N(C3=CC4C(C=C3)C3C=CC=CC3N4c3cccc(-n4c5ccccc5c5ccccc54)c3)C2C=C1]

and the thickness of the electron blocking layer may be 10 nm.
S05: forming a luminescent layer EML on the electron blocking layer.

As an example, the material of the luminescent layer comprises the host material and a guest material (Dopant), wherein the content of the host material is 90%, and the content of the guest material is 10%.

As an example, the thickness of the luminescent layer may be 25 nm.

As an example, the guest material may comprise the thermally activated delayed-fluorescence material.

As an example, the host material comprises

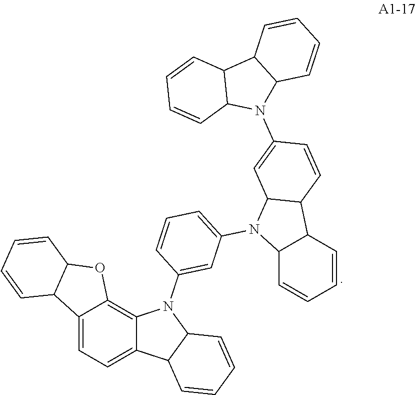 [SMILES: C1=CC2Oc3c(ccc4c3N(c3cccc(N5C6C=CC=CC6C6C=CC(N7C8C=CC=CC8C8C=CC=CC87)=CC65)c3)C3C=CC=CC43)C2C=C1]

S06: forming a hole blocking layer HBL on the luminescent layer.

As an example, the thickness of the hole blocking layer may be 10 nm, and the material of the hole blocking layer may comprise

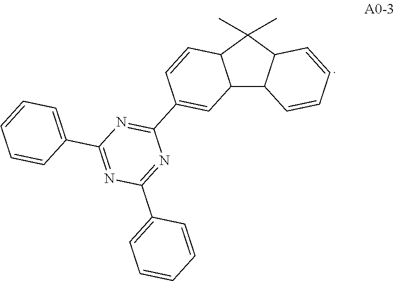 [SMILES: CC1(C)C2C=CC=CC2C2C=C(c3nc(-c4ccccc4)nc(-c4ccccc4)n3)C=CC21]

S07: forming an electron transporting layer ETL on the luminescent layer.

As an example, the thickness of the electron transporting layer may be 30 nm.
S08: sequentially forming a LiF layer and a cathode on the electron transporting layer, wherein the thickness of the LiF layer is 1 nm, and the thickness of the cathode is 80 nm.

As an example, the material of the cathode may be aluminum (Al).

The film-layer structure of the first type of the light emitting device according to the embodiments of the present application sequentially comprises: ITO/HIL/HTL/A1-11/A1-17:dopant/A0-3/ETL/LiF/Al.

The method for fabricating the second type of the light emitting device according to the embodiments of the present application is as follows:
S11: forming an anode Anode on a glass substrate by vacuum vapor deposition, wherein the thickness of the anode may be 100 nm, and the material of the anode is indium tin oxide (ITO).
S12: depositing a hole-injection material on the anode by vacuum vapor deposition, to form a hole injection layer HIL.

As an example, the thickness of the hole injection layer may be 10 nm.
S13: forming a hole transporting layer HTL on the hole injection layer.

As an example, the thickness of the hole transporting layer may be 60 nm.
S14: forming an electron blocking layer EBL on the hole transporting layer.

The material of the electron blocking layer comprises

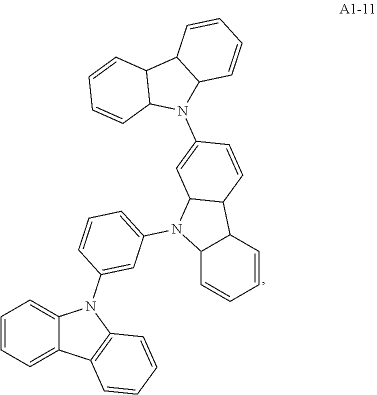 [SMILES: C1=CC2C3C=CC=CC3N(C3=CC4C(C=C3)C3C=CC=CC3N4c3cccc(-n4c5ccccc5c5ccccc54)c3)C2C=C1]

and the thickness of the electron blocking layer may be 10 nm.
S15: forming a luminescent layer EML on the electron blocking layer.

As an example, the material of the luminescent layer comprises the host material, a sensitizer and a guest material (Dopant), wherein the content of the host material is 79%, the content of the guest material is 1%, and the content of the sensitizer TH is 20%.

As an example, the thickness of the luminescent layer may be 25 nm.

As an example, the guest material may comprise the thermally activated delayed-fluorescence material.

As an example, the host material comprises

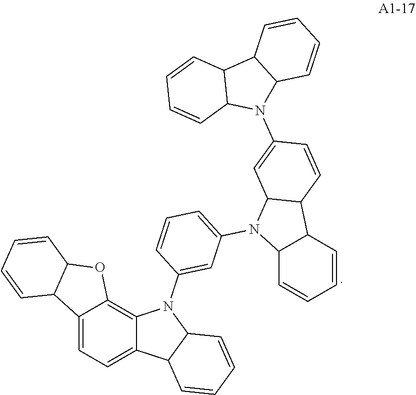 [SMILES: C1=CC2Oc3c(ccc4c3N(c3cccc(N5C6C=CC=CC6C6C=CC(N7C8C=CC=CC8C8C=CC=CC87)=CC65)c3)C3C=CC=CC43)C2C=C1]

S16: forming a hole blocking layer HBL on the luminescent layer.

As an example, the thickness of the hole blocking layer may be 10 nm, and the material of the hole blocking layer may comprise

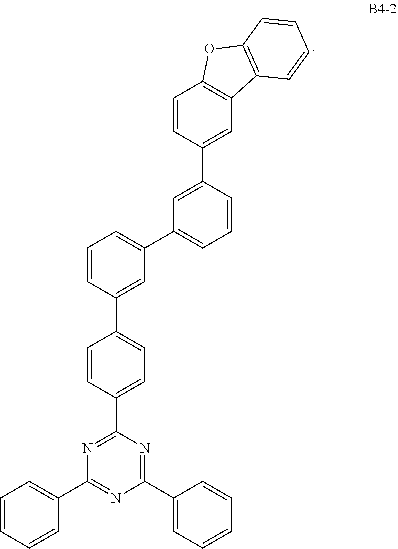 [SMILES: c1ccc(-c2nc(-c3ccccc3)nc(-c3ccc(-c4cccc(-c5cccc(-c6ccc7oc8ccccc8c7c6)c5)c4)cc3)n2)cc1]

S17: forming an electron transporting layer ETL on the luminescent layer.

As an example, the thickness of the electron transporting layer may be 30 nm.
S18: sequentially forming a LiF layer and a cathode on the electron transporting layer, wherein the thickness of the LiF layer is 1 nm, and the thickness of the cathode is 80 nm.

As an example, the material of the cathode may be aluminum (Al).

The film-layer structure of the second type of the light emitting device according to the embodiments of the present application sequentially comprises: ITO/HIL/HTL/A1-11/A1-17:TH:dopant/B4-2/ETL/LiF/Al.

The method for fabricating the third type of the light emitting device according to the embodiments of the present application is as follows:
S21: depositing an anode Anode on a glass substrate by vacuum vapor deposition, wherein the thickness of the anode may be 100 nm, and the material of the anode is indium tin oxide (ITO).
S22: depositing a hole-injection material on the anode by vacuum vapor deposition, to form a hole injection layer HIL.

As an example, the thickness of the hole injection layer may be 10 nm.
S23: forming a hole transporting layer HTL on the hole injection layer.

As an example, the thickness of the hole transporting layer may be 60 nm.
S24: forming an electron blocking layer EBL on the hole transporting layer.

The material of the electron blocking layer comprises

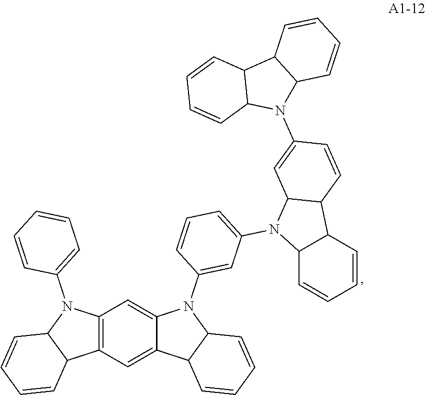 [SMILES: C1=CC2c3cc4c(cc3N(c3ccccc3)C2C=C1)N(c1cccc(N2C3C=CC=CC3C3C=CC(N5C6C=CC=CC6C6C=CC=CC65)=CC32)c1)C1C=CC=CC41]

and the thickness of the electron blocking layer may be 10 nm.
S25: forming a luminescent layer EML on the electron blocking layer.

As an example, the material of the luminescent layer comprises the host material and a guest material (Dopant), wherein the content of the host material is 90%, and the content of the guest material is 10%.

As an example, the thickness of the luminescent layer may be 25 nm.

As an example, the guest material may comprise the thermally activated delayed-fluorescence material.

As an example, the host material comprises

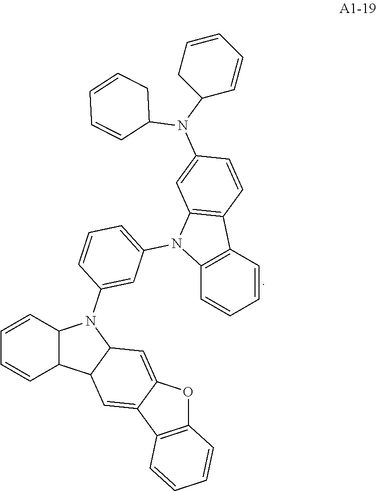 [SMILES: C1=CCC(N(c2ccc3c4ccccc4n(-c4cccc(N5C6C=CC=CC6C6C=c7c(oc8ccccc78)=CC65)c4)c3c2)C2C=CC=CC2)C=C1]

S26: forming a hole blocking layer HBL on the luminescent layer.

As an example, the thickness of the hole blocking layer may be 10 nm, and the material of the hole blocking layer may comprise

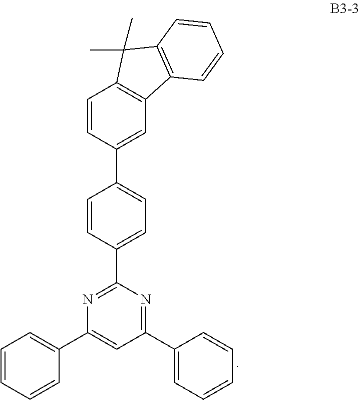 [SMILES: CC1(C)c2ccccc2-c2cc(-c3ccc(-c4nc(-c5ccccc5)cc(-c5ccccc5)n4)cc3)ccc21]

S27: forming an electron transporting layer ETL on the luminescent layer.

As an example, the thickness of the electron transporting layer may be 30 nm.
S28: sequentially forming a LiF layer and a cathode on the electron transporting layer, wherein the thickness of the LiF layer is 1 nm, and the thickness of the cathode is 80 nm.

As an example, the material of the cathode may be aluminum (Al).

The film-layer structure of the third type of the light emitting device according to the embodiments of the present application sequentially comprises: ITO/HIL/HTL/Al-12/Al-19:dopant/B3-3/ETL/LiF/Al.

The method for fabricating the first type of the light emitting device in the related art is as follows:
S31: depositing an anode Anode on a glass substrate by vacuum vapor deposition, wherein the thickness of the anode may be 100 nm, and the material of the anode is indium tin oxide (ITO).
S32: depositing a hole-injection material on the anode by vacuum vapor deposition, to form a hole injection layer HIL.

As an example, the thickness of the hole injection layer may be 10 nm.
S33: forming a hole transporting layer HTL on the hole injection layer.

As an example, the thickness of the hole transporting layer may be 60 nm.
S34: forming an electron blocking layer EBL on the hole transporting layer.

The material of the electron blocking layer comprises TCTA, and the thickness of the electron blocking layer may be 10 nm.

The structure of TCTA is as follows:

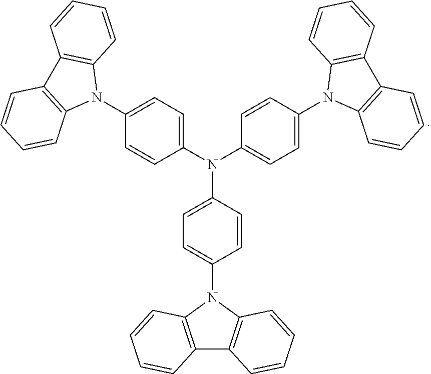 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

S35: forming a luminescent layer EML on the electron blocking layer.

As an example, the material of the luminescent layer comprises the host material and a guest material (Dopant), wherein the content of the host material is 97%, and the content of the guest material is 3%.

As an example, the thickness of the luminescent layer may be 25 nm.

As an example, the host material may comprise mCPB.

The structure of mCPB is as follows:

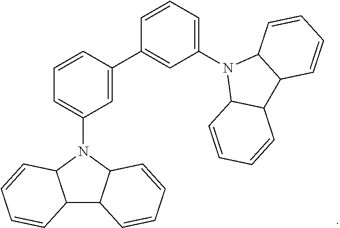 [SMILES: C1=CC2C3C=CC=CC3N(c3cccc(-c4cccc(N5C6C=CC=CC6C6C=CC=CC65)c4)c3)C2C=C1]

S36: forming a hole blocking layer HBL on the luminescent layer.

As an example, the thickness of the hole blocking layer may be 10 nm, and the material of the hole blocking layer may comprise B3PYMPM.

The structure of B3PYMPM is as follows:

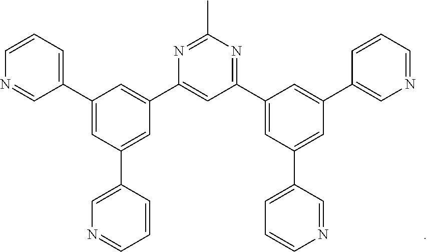

S37: forming an electron transporting layer ETL on the luminescent layer.

As an example, the thickness of the electron transporting layer may be 30 nm.

S38: sequentially forming a LiF layer and a cathode on the electron transporting layer, wherein the thickness of the LiF layer is 1 nm, and the thickness of the cathode is 80 nm.

As an example, the material of the cathode may be aluminum (Al).

The film-layer structure of the first type of the light emitting device in the related art sequentially comprises:

ITO/HIL/HTL/TCTA/mCBP:dopant/B3PYMPM/ETL/LiF/Al.

The method for fabricating the second type of the light emitting device in the related art is as follows:

S41: depositing an anode Anode on a glass substrate by vacuum vapor deposition, wherein the thickness of the anode may be 100 nm, and the material of the anode is indium tin oxide (ITO).

S42: depositing a hole-injection material on the anode by vacuum vapor deposition, to form a hole injection layer HIL.

As an example, the thickness of the hole injection layer may be 10 nm.

S43: forming a hole transporting layer HTL on the hole injection layer.

As an example, the thickness of the hole transporting layer may be 60 nm.

S44: forming an electron blocking layer EBL on the hole transporting layer.

The material of the electron blocking layer comprises TCTA, and the thickness of the electron blocking layer may be 10 nm.

The structure of TCTA is as follows:

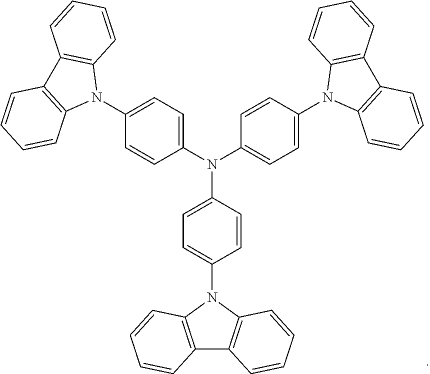 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

S45: forming a luminescent layer EML on the electron blocking layer.

As an example, the material of the luminescent layer comprises the host material and a guest material (Dopant), wherein the content of the host material is 97%, and the content of the guest material is 3%.

As an example, the thickness of the luminescent layer may be 25 nm.

As an example, the host material may comprise mCPB.

The structure of mCPB is as follows:

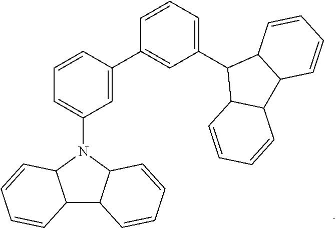 [SMILES: C1=CC2C3C=CC=CC3C(c3cccc(-c4cccc(N5C6C=CC=CC6C6C=CC=CC65)c4)c3)C2C=C1]

S46: forming a hole blocking layer HBL on the luminescent layer.

As an example, the thickness of the hole blocking layer may be 10 nm, and the material of the hole blocking layer may comprise B2.

The structure of B2 is as follows:

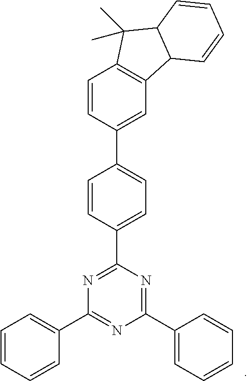 [SMILES: CC1(C)c2ccc(-c3ccc(-c4nc(-c5ccccc5)nc(-c5ccccc5)n4)cc3)cc2C2C=CC=CC21]

S47: forming an electron transporting layer ETL on the luminescent layer.

As an example, the thickness of the electron transporting layer may be 30 nm.

S48: sequentially forming a LiF layer and a cathode on the electron transporting layer, wherein the thickness of the LiF layer is 1 nm, and the thickness of the cathode is 80 nm. As an example, the material of the cathode may be aluminum (Al).

The film-layer structure of the second type of the light emitting device in the related art sequentially comprises:

ITO/HIL/HTL/TCTA/mCBP:dopant/B2/ETL/LiF/Al.

The relevant test data of the three types of the light emitting device according to the embodiments of the present application and the two types of the light emitting device in the related art will be described below.

TABLE 1
performance parameters of some of the materials of the three types
of the light emitting device according to the present application
and the two types of the light emitting device in the related art

| | S1 (eV) | T1 (eV) | HOMO (eV) | LUMO (eV) |
|---|---|---|---|---|
| A1-11 | 3.53 | 2.81 | −5.88 | −2.53 |
| A1-12 | 3.55 | 2.83 | −5.88 | −2.51 |
| A1-17 | 3.51 | 2.77 | −6.07 | −2.56 |
| A1-19 | 3.53 | 2.81 | −6.15 | −2.77 |
| A0-3 | 3.45 | 2.87 | −6.25 | −2.78 |
| B4-2 | 3.50 | 2.90 | −6.23 | −2.77 |
| B3-3 | 3.63 | 2.92 | −6.28 | −2.75 |
| TCTA | 3.65 | 3.0 | −5.7 | −2.4 |
| mCBP | 3.42 | 3.08 | −6.1 | −2.6 |
| B3PYMPM | 3.47 | 2.85 | −6.7 | −3.3 |
| B2 | 3.37 | 2.60 | −6.25 | −2.77 |
| Dopant | 2.1 | 2.0 | −5.14 | −2.96 |

TABLE 2
device performance data of the three types of the light emitting
device according to the present application and the two types
of the light emitting device in the related art

| | Current density | Voltage | Efficiency | LT₉₀ |
|---|---|---|---|---|
| Device | (mA/cm²) | (V) | (cd/A) | (h) |
| Example 1 | 10 | 95% | 129% | 277% |
| Example 2 | 10 | 97% | 233% | 410% |
| Example 3 | 10 | 95% | 187% | 130% |
| Comparative | 10 | 100% | 100% | 100% |
| Example 1 | | | | |
| Comparative | 10 | 100% | 113% | 71% |
| Example 2 | | | | |

Example 1 represents the first type of the light emitting device according to the embodiments of the present application, Example 2 represents the second type of the light emitting device according to the embodiments of the present application, Example 3 represents the third type of the light emitting device according to the embodiments of the present application, comparative Example 1 represents the first type of the light emitting device in the related art, and Comparative Example 2 represents the second type of the light emitting device in the related art.

According to the data in Table 2, it can be known that, with the equal current density, as compared with the two types of the light emitting device in the related art, the luminous efficiencies and the service lives of all of the three types of the light emitting device according to the embodiments of the present application are obviously increased, and the working voltages are reduced. It should be noted that LT90 (h) refers to the duration that has been spent when the real-time brightness of the light emitting device is 90% of the initial brightness, and can reflect the service life of the light emitting device.

An embodiment of the present application further provides a light emitting device. Referring to FIG. 1, the light emitting device comprises:
a first electrode 1 and a second electrode 9;
a luminescent layer 5, located between the first electrode 1 and the second electrode 9, comprising a host material and a thermally activated delayed-fluorescence material;
an electron blocking layer 4, located between the luminescent layer 5 and the first electrode 1; and
a hole blocking layer 6, located between the luminescent layer 5 and the second electrode 9; and
the material of the electron blocking layer 4 and the structure of the host material individually comprise

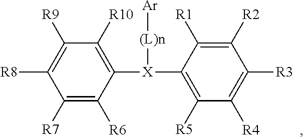

and
the structure of the material of the hole blocking layer 6 comprises

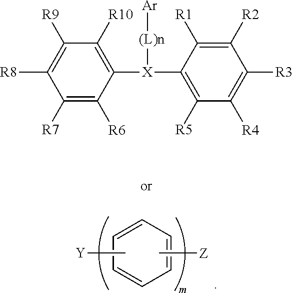

In some embodiments of the present application, X comprises one of a boron atom, a carbon atom, a nitrogen atom, an oxygen atom, a silicon atom, a phosphorus atom and a sulphur atom;
L comprises one of substituted or unsubstituted C6-C20 arylene and substituted or unsubstituted C3-C30 heteroarylene, and n is one of 0, 1 and 2; and
m is greater than or equal to 3.

In some embodiments of the present application, Y and Z individually comprise hydrogen, diplogen, halogen group, nitrile group, nitro, hydroxyl, carbonyl, ester group, imide group, amino, substituted or unsubstituted C3-C30 silyl, substituted or unsubstituted boryl, substituted or unsubstituted C1-C30 alkyl, substituted or unsubstituted C3-C30 cycloalkyl, substituted or unsubstituted alkoxy, substituted or unsubstituted aryloxy, substituted or unsubstituted alkylsulfenyl, substituted or unsubstituted arylsulfenyl, substituted or unsubstituted alkylsulfonyl, substituted or unsubstituted C6-C30 arylsulfonyl, substituted or unsubstituted alkenyl, substituted or unsubstituted aralkyl, substituted or unsubstituted aralkenyl, substituted or unsubstituted alkaryl, substituted or unsubstituted alkylamido, substituted or unsubstituted C1-C30 aralkylamido, substituted or unsubstituted C6-C30 heteroarylamido, substituted or unsubstituted C6-C30 arylamido, substituted or unsubstituted C6-C30 arylheteroarylamido, substituted or unsubstituted C6-C30 arylphosphino, substituted or unsubstituted phosphine oxide group, substituted or unsubstituted C6-C30 aryl, substituted or unsubstituted heterocyclic group, substituted or unsubstituted C1-C30 alkyl C6-C30 diarylsilyl, and substituted or unsubstituted C3-C30 monocyclic or polycyclic alicyclic ring or aromatic ring; and
if at least one of X and Y comprises the substituted or unsubstituted C3-C30 monocyclic or polycyclic alicyclic ring or aromatic ring, the alicyclic ring or aromatic ring comprises at least one heteroatom, and the heteroatom comprises oxygen atom, sulphur atom or nitrogen atom.

In some embodiments of the present application, R1-R10 individually comprise one of hydrogen, C-C12 alkyl, substituted or unsubstituted C6-C30 arylene and substituted or unsubstituted C3-C30 heteroarylene, and at least one pair of two neighboring groups among R1-R10 are connected to form a ring; and
Ar comprises one of hydrogen, C1-C12 alkyl, substituted or unsubstituted C6-C30 arylene and substituted or unsubstituted C3-C30 heteroarylene.

In an exemplary embodiment,
the particular structures of

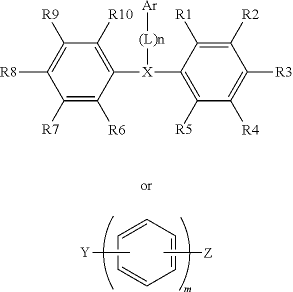

may refer to the above description, and are not discussed further herein.

In some embodiments of the present application, 0.1 eV<|HOMO_{EBL}−HOMO_{Host}|≤0.3 eV,
wherein HOMO_{EBL} refers to the energy value of the highest occupied molecular orbital HOMO of the material of the electron blocking layer, and HOMO_{Host} refers to the energy value of the highest occupied molecular orbital HOMO of the host material; and

0.1eV<|LUMO_{HBL}−LUMO_{Host}|≤0.3 eV,
wherein LUMO_{HBL} refers to the energy value of the lowest unoccupied molecular orbital LUMO of the material of the hole blocking layer, and LUMO_{Host} refers to the energy value of the lowest unoccupied molecular orbital LUMO of the host material.

In the embodiments of the present application, by configuring that the absolute value of the difference between the energy value of the highest occupied molecular orbital HOMO of the material of the electron blocking layer 4 and the energy value of the highest occupied molecular orbital HOMO of the host material Host is greater than 0.1 eV and less than or equal to 0.3 eV, the degree of the matching between the host material of the luminescent layer and the material of the electron blocking layer is increased, to facilitate the holes to be transmitted from the electron blocking layer and injected into the luminescent layer, whereby as many holes as possible are injected into the host material of the luminescent layer and recombine with the electrons in the luminescent layer to form excitons, and the excitons have radioluminescence, thereby increasing the luminous efficiency of the light emitting device. Additionally, the electron blocking layer can, to a large extent, prevent the electrons from leaking from the luminescent layer to the side of the electron blocking layer that is closer to the first electrode 1, which increases the service life of the light emitting device to a large extent.

Additionally, by configuring that the absolute value of the difference between the energy value of the highest occupied molecular orbital HOMO of the material of the electron blocking layer 4 and the energy value of the highest occupied molecular orbital HOMO of the host material Host is greater than 0.1 eV and less than or equal to 0.3 eV, and further configuring that the absolute value of the difference between the energy value of the lowest unoccupied molecular orbital LUMO of the material of the hole blocking layer 6 and the energy value of the lowest unoccupied molecular orbital LUMO of the host material is greater than 0.1 eV and less than or equal to 0.3 eV, the degree of the matching between the host material of the luminescent layer 5 and the material of the electron blocking layer 4 is increased, and the degree of the matching between the host material of the luminescent layer 5 and the material of the hole blocking layer 6 is also increased, whereby as many holes and electrons as possible are injected into the host material of the luminescent layer and reach balance in the luminescent layer, thereby preventing the electrons or the holes from leaking from the luminescent layer. Accordingly, in an aspect, the service life of the light emitting device can be increased, and, in another aspect, the holes and the electrons recombine in the luminescent layer to form excitons, and the excitons have radioluminescence, which increases the utilization ratio of the recombination between the holes and the electrons to form the excitons, thereby increasing the luminous efficiency of the light emitting device.

In some embodiments of the present application, T1_{EBL}−T1_{TADF}>0.1 eV, and S1_{EBL}−S1_{TADF}>0; and

T1_{HBL}−T1_{TADF}>0, and S1_{HBL}−S1_{TADF}>0;
wherein T1_{EBL} refers to the energy value of the first-triplet-state energy level of the material of the electron blocking layer, T1_{TADF} refers to the energy value of the first-triplet-state energy level of the thermally activated delayed-fluorescence material, S1_{EBL} refers to the energy value of the first-singlet-state energy level of the material of the electron blocking layer, and S1_{TADF} refers to the energy value of the first-singlet-state energy level of the thermally activated delayed-fluorescence material; and
T1_{HBL} refers to the energy value of the first-triplet-state energy level of the material of the hole blocking layer, and S1_{HBL} refers to the energy value of the first-singlet-state energy level of the material of the hole blocking layer.

In the embodiments of the present application, as compared with the thermally activated delayed-fluorescence material, the electron blocking layer that has a higher energy value T1_{EBL} of the first-triplet-state energy level and a higher energy value S1_{EBL} of the first-singlet-state energy level facilitates to prevent electron leakage, and can prevent the excitons in the thermally activated delayed-fluorescence material from leaking into the electron blocking layer, thereby facilitating to increase the luminous efficiency of the luminescent layer.

In the embodiments of the present application, as compared with the thermally activated delayed-fluorescence material, the hole blocking layer that has a higher energy value T1_{HBL} of the first-triplet-state energy level and a higher energy value S1_{HBL} of the first-singlet-state energy level facilitates to prevent hole leakage, and can prevent the excitons in the thermally activated delayed-fluorescence material from leaking into the hole blocking layer, thereby facilitating to increase the luminous efficiency of the luminescent layer.

It should be noted that, in the embodiments of the present application, the magnitude relation between the energy value T1_{Host} of the first-triplet-state energy level of the host material of the luminescent layer and the energy value T1_{TADF} of the first-triplet-state energy level of the thermally activated delayed-fluorescence material of the luminescent layer is not limited, and may be particularly determined according to the type of the host material and the type of the thermally activated delayed-fluorescence material in practical applications. That may be particularly determined according to the material design of the luminescent layer.

In some embodiments, T1_{Host}−T1_{TADF}>0. In some other embodiments, T1Host-T1_{TADF}<0.

In the embodiments of the present application, because the energy levels of the material of the electron blocking layer, the host material and the material of the hole blocking layer are different, although all of the materials of them may comprise the above general structural formulas, in practical situations, the structures of the materials of them are not completely the same.

In some embodiments of the present application, the light emitting device further comprises a hole transporting layer 3, and the hole transporting layer 3 is located between the electron blocking layer 4 and the first electrode 1;

0.1eV<|HOMO_{HTL}−HOMO_{EBL}|≤0.3 eV,
wherein HOMO_{HTL} refers to the energy value of the highest occupied molecular orbital HOMO of the material of the hole transporting layer;
the light emitting device further comprises an electron transporting layer 7, and the electron transporting layer 7 is located between the hole blocking layer 6 and the second electrode 9; and

0.1 eV<|LUMO_{HBL}−LUMO_{ETL}|≤0.3 eV,
wherein LUMO_{ETL} refers to the energy value of the lowest unoccupied molecular orbital LUMO of the material of the electron transporting layer.

In the embodiments of the present application, by configuring that the absolute value of the difference between the energy value HOMO_{HTL} of the highest occupied molecular orbital HOMO of the material of the hole transporting layer 3 and the energy value HOMO_{EBL} of the highest occupied molecular orbital HOMO of the material of the electron blocking layer 4 is greater than 0.1 eV and less than or equal to 0.3 eV, the degree of the matching between the HOMO energy levels of the material of the hole transporting layer 3 and the material of the electron blocking layer 4 is increased, whereby the holes can, from the hole transporting layer 3, pass through the electron blocking layer 4 and be injected into the luminescent layer 5 with a high efficiency, which can increase the luminous efficiency of the light emitting device while increasing the lives of the film layers of the light emitting device. By configuring that the absolute value of the difference between the energy value LUMO_{HBL} of the lowest unoccupied molecular orbital LUMO of the material of the hole blocking layer 6 and the energy value LUMO_{ETL} of the lowest unoccupied molecular orbital LUMO of the material of the electron transporting layer 7 is greater than 0.1 eV and less than or equal to 0.3 eV, the degree of the matching between the LUMO energy levels of the material of the hole blocking layer 6 and the material of the electron transporting layer 7 is increased, whereby the electrons can, from the electron transporting layer 7, pass through the hole blocking layer 6 and be injected into the luminescent layer 5 with a high efficiency, which can increase the luminous efficiency of the light emitting device while increasing the lives of the film layers of the light emitting device.

In an exemplary embodiment, the thickness of the luminescent layer in the direction perpendicular to the plane where the first electrode is located ranges 15 nm-45 nm;
the thickness of the electron blocking layer in the direction perpendicular to the plane where the first electrode is located ranges 1 nm-15 nm; and
the thickness of the hole blocking layer in the direction perpendicular to the plane where the first electrode is located ranges 1 nm-15 nm.

As an example, the thickness of the luminescent layer may be 25 nm, the thickness of the electron blocking layer may be 10 nm, and the thickness of the hole blocking layer may be 10 nm.

As an example, if the wavelength of the light ray emitted by the luminescent layer is greater than or equal to 600 nm, the thickness of the luminescent layer ranges 15 nm-35 nm.

As an example, in the same one light emitting device, the ratio of the thickness of the electron blocking layer to the thickness of the luminescent layer ranges 1:2-1:10. For example, the ratio of the thickness of the electron blocking layer to the thickness of the luminescent layer is 1:7. As another example, the ratio of the thickness of the electron blocking layer to the thickness of the luminescent layer is 1:9.

An embodiment of the present application provides a displaying device, wherein the displaying device comprises the light emitting device stated above.

The displaying device may be a flexible displaying device (also referred to as a flexible screen), and may also be a rigid displaying device (i.e., a displaying device that cannot be bent), which is not limited herein. The displaying device may be an OLED (Organic Light Emitting Diode) displaying device, and may also be any products or components having a displaying function that comprise an OLED, such as a television set, a digital camera, a mobile phone and a tablet personal computer. The displaying device has the advantages such as a good displaying effect, a long life and a high stability.

The above are merely particular embodiments of the present application, and the protection scope of the present application is not limited thereto. All of the variations or substitutions that a person skilled in the art can easily envisage within the technical scope disclosed by the present application should fall within the protection scope of the present application. Therefore, the protection scope of the present application should be subject to the protection scope of the claims.

1. A light emitting device, wherein the light emitting device comprises:
a first electrode and a second electrode;
a luminescent layer, located between the first electrode and the second electrode, comprising a host material and a thermally activated delayed-fluorescence material; and
an electron blocking layer, located between the luminescent layer and the first electrode; and
0.1 eV<|HOMO_{EBL}−HOMO_{Host}|≤0.3 eV,
wherein HOMO_{EBL} refers to an energy value of a highest occupied molecular orbital HOMO of a material of the electron blocking layer, and HOMO_{Host} refers to an energy value of a highest occupied molecular orbital HOMO of the host material.

2. The light emitting device according to claim 1, wherein the light emitting device further comprises a hole blocking layer, and the hole blocking layer is located between the luminescent layer and the second electrode; and
0.1 eV<|LUMO_{HBL}−LUMO_{Host}|≤0.3 eV,
wherein LUMO_{HBL} refers to an energy value of a lowest unoccupied molecular orbital LUMO of a material of the hole blocking layer, and LUMO_{Host} refers to an energy value of a lowest unoccupied molecular orbital LUMO of the host material.

3. The light emitting device according to claim 2, wherein
T1_{EBL}−T1_{TADF}≥0.1eV, and S1_{EBL}−S1_{TADF}>0; and
T1_{HBL}−T1_{TADF}>0, and S1_{HBL}−S1_{TADF}>0;
wherein T1_{EBL} refers to an energy value of a first-triplet-state energy level of the material of the electron blocking layer, T1_{TADF} refers to an energy value of a first-triplet-state energy level of the thermally activated delayed-fluorescence material, S1_{EBL} refers to an energy value of a first-singlet-state energy level of the material of the electron blocking layer, and S1_{TADF} refers to an energy value of a first-singlet-state energy level of the thermally activated delayed-fluorescence material; and
T1_{HBL} refers to an energy value of a first-triplet-state energy level of a material of a hole blocking layer, and S1_{HBL} refers to an energy value of a first-singlet-state energy level of the material of the hole blocking layer.

4. The light emitting device according to claim 2, wherein the material of the electron blocking layer, the host material and the material of the hole blocking layer individually comprise: 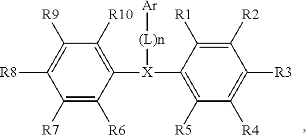
wherein X comprises one of a boron atom, a carbon atom, a nitrogen atom, an oxygen atom, a silicon atom, a phosphorus atom and a sulphur atom, L comprises one of substituted or unsubstituted C6-C20 arylene and substituted or unsubstituted C3-C30 heteroarylene, and n is one of 0, 1 and 2.

5. The light emitting device according to claim 4, wherein R1-R10 individually comprise one of hydrogen, C-C12 alkyl, substituted or unsubstituted C6-C30 arylene and substituted or unsubstituted C3-C30 heteroarylene, and at least one pair of two neighboring groups among R1-R10 are connected to form a ring.

6. The light emitting device according to claim 4, wherein Ar comprises one of hydrogen, C1-C12 alkyl, substituted or unsubstituted C6-C30 arylene and substituted or unsubstituted C3-C30 heteroarylene.

7. The light emitting device according to claim 2, wherein the material of the hole blocking layer comprises: 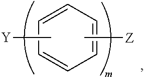
wherein Y and Z individually comprise hydrogen, diplogen, halogen group, nitrile group, nitro, hydroxyl, carbonyl, ester group, imide group, amino, substituted or unsubstituted C3-C30 silyl, substituted or unsubstituted boryl, substituted or unsubstituted C1-C30 alkyl, substituted or unsubstituted C3-C30 cycloalkyl, substituted or unsubstituted alkoxy, substituted or unsubstituted aryloxy, substituted or unsubstituted alkylsulfenyl, substituted or unsubstituted arylsulfenyl, substituted or unsubstituted alkylsulfonyl, substituted or unsubstituted C6-C30 arylsulfonyl, substituted or unsubstituted alkenyl, substituted or unsubstituted aralkyl, substituted or unsubstituted aralkenyl, substituted or unsubstituted alkaryl, substituted or unsubstituted alkylamido, substituted or unsubstituted C1-C30 aralkylamido, substituted or unsubstituted C6-C30 heteroarylamido, substituted or unsubstituted C6-C30 arylamido, substituted or unsubstituted C6-C30 arylheteroarylamido, substituted or unsubstituted C6-C30 arylphosphino, substituted or unsubstituted phosphine oxide group, substituted or unsubstituted C6-C30 aryl, substituted or unsubstituted heterocyclic group, substituted or unsubstituted C1-C30 alkyl C6-C30 diarylsilyl, and substituted or unsubstituted C3-C30 monocyclic or polycyclic alicyclic ring or aromatic ring; and
if at least one of X and Y comprises the substituted or unsubstituted C3-C30 monocyclic or polycyclic alicyclic ring or aromatic ring, the alicyclic ring or aromatic ring comprises at least one heteroatom, and the heteroatom comprises oxygen atom, sulphur atom or nitrogen atom.

8. The light emitting device according to claim 7, wherein m is greater than or equal to 3;
if m=3, 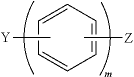
comprises: 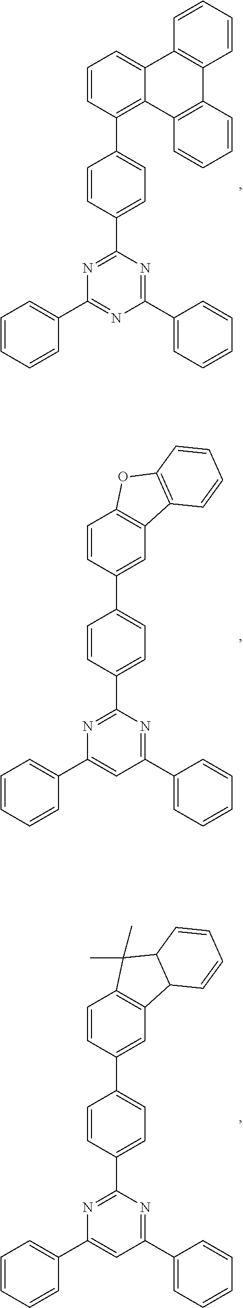 [SMILES: c1ccc(-c2nc(-c3ccccc3)nc(-c3ccc(-c4cccc5c6ccccc6c6ccccc6c45)cc3)n2)cc1 ; c1ccc(-c2cc(-c3ccccc3)nc(-c3ccc(-c4ccc5oc6ccccc6c5c4)cc3)n2)cc1 ; CC1(C)c2ccc(-c3ccc(-c4nc(-c5ccccc5)cc(-c5ccccc5)n4)cc3)cc2C2C=CC=CC21] 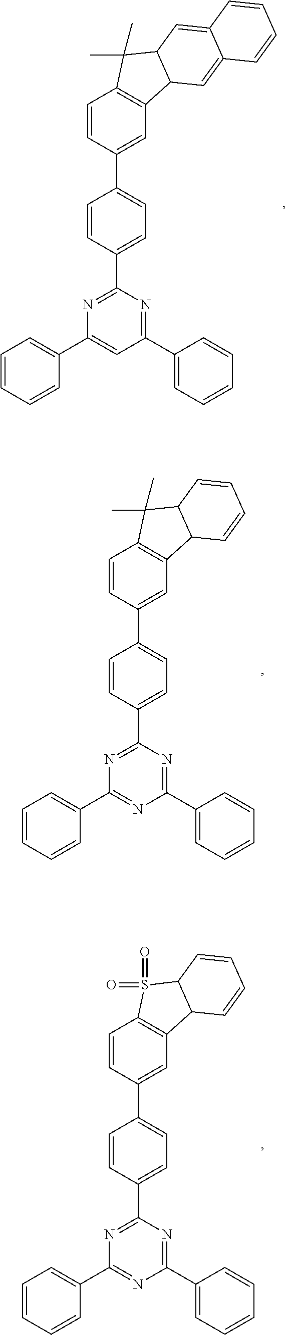 [SMILES: CC1(C)c2ccc(-c3ccc(-c4nc(-c5ccccc5)cc(-c5ccccc5)n4)cc3)cc2C2C=c3ccccc3=CC21 ; CC1(C)c2ccc(-c3ccc(-c4nc(-c5ccccc5)nc(-c5ccccc5)n4)cc3)cc2C2C=CC=CC21 ; O=S1(=O)c2ccc(-c3ccc(-c4nc(-c5ccccc5)nc(-c5ccccc5)n4)cc3)cc2C2C=CC=CC21] 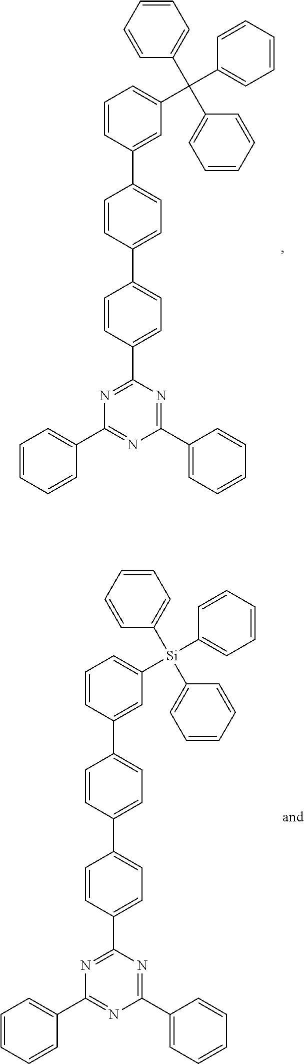 [SMILES: c1ccc(-c2nc(-c3ccccc3)nc(-c3ccc(-c4ccc(-c5cccc(C(c6ccccc6)(c6ccccc6)c6ccccc6)c5)cc4)cc3)n2)cc1 ; c1ccc(-c2nc(-c3ccccc3)nc(-c3ccc(-c4ccc(-c5cccc([Si](c6ccccc6)(c6ccccc6)c6ccccc6)c5)cc4)cc3)n2)cc1] 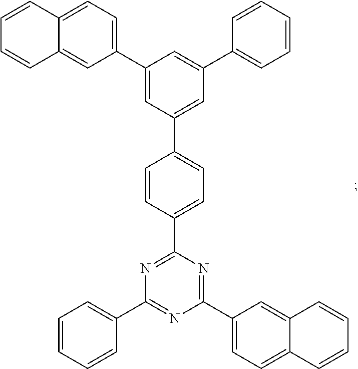 [SMILES: c1ccc(-c2cc(-c3ccc(-c4nc(-c5ccccc5)nc(-c5ccc6ccccc6c5)n4)cc3)cc(-c3ccc4ccccc4c3)c2)cc1]
and
if m=4, 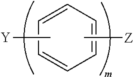
comprises:

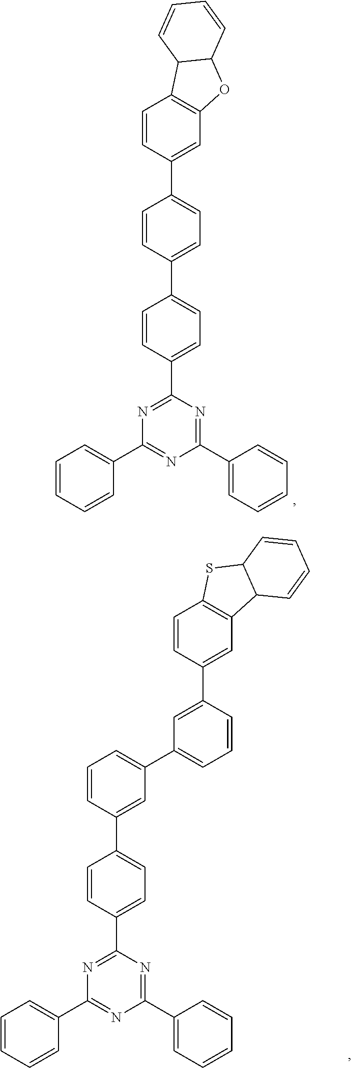

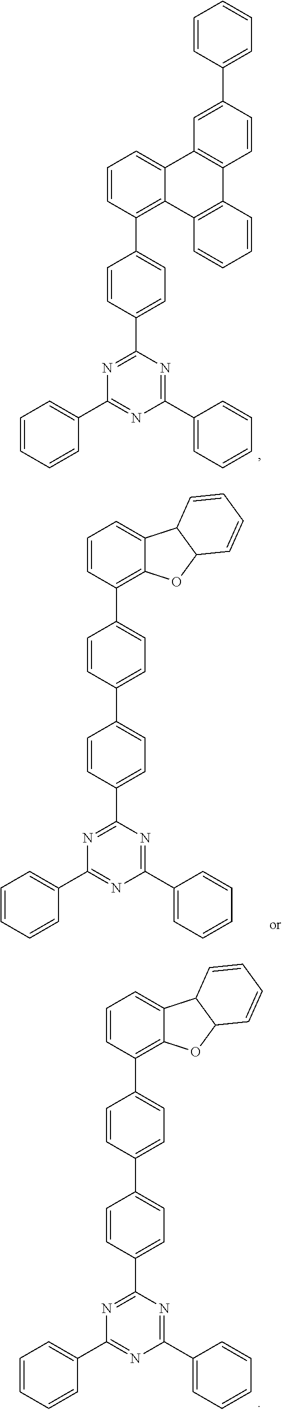

9. The light emitting device according to claim 2, wherein the light emitting device further comprises a hole transporting layer, and the hole transporting layer is located between the electron blocking layer and the first electrode;
0.1 eV<|HOMO_{HTL}−HOMO_{EBL}|≤0.3 eV,
wherein HOMO_{HTL} refers to an energy value of a highest occupied molecular orbital HOMO of a material of the hole transporting layer;
the light emitting device further comprises an electron transporting layer, and the electron transporting layer is located between the hole blocking layer and the second electrode; and
0.1 eV<|LUMO_{HBL}−LUMO_{ETL}|≤0.3 eV,
wherein LUMO_{ETL} refers to an energy value of a lowest unoccupied molecular orbital LUMO of a material of the electron transporting layer.

10. The light emitting device according to claim 4, wherein
T1_{Host}≥2.45 eV, T1_{EBL}≥2.55 eV, and S1_{EBL}≥2.90 eV; and

|HOMO_{EBL}|≥5.6 eV, and HOMO_{Host}|≥5.8 eV.

11. The light emitting device according to claim 4, wherein
S1_{HBL}≥3.00eV, and T1_{HBL}≥2.60 eV.

12. A light emitting device, wherein the light emitting device comprises:
a first electrode and a second electrode;
a luminescent layer, located between the first electrode and the second electrode, comprising a host material and a thermally activated delayed-fluorescence material;
an electron blocking layer, located between the luminescent layer and the first electrode; and
a hole blocking layer, located between the luminescent layer and the second electrode; and
a material of the electron blocking layer and a structure of the host material individually comprise 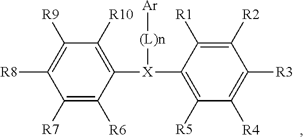
and
a structure of a material of the hole blocking layer comprises

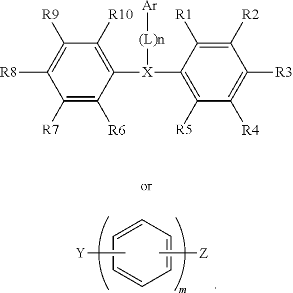

13. The light emitting device according to claim 12, wherein X comprises one of a boron atom, a carbon atom, a nitrogen atom, an oxygen atom, a silicon atom, a phosphorus atom and a sulphur atom;
L comprises one of substituted or unsubstituted C6-C20 arylene and substituted or unsubstituted C3-C30 heteroarylene, and n is one of 0, 1 and 2; and
m is greater than or equal to 3.

14. The light emitting device according to claim 13, wherein Y and Z individually comprise hydrogen, diplogen, halogen group, nitrile group, nitro, hydroxyl, carbonyl, ester group, imide group, amino, substituted or unsubstituted C3-C30 silyl, substituted or unsubstituted boryl, substituted or unsubstituted C1-C30 alkyl, substituted or unsubstituted C3-C30 cycloalkyl, substituted or unsubstituted alkoxy, substituted or unsubstituted aryloxy, substituted or unsubstituted alkylsulfenyl, substituted or unsubstituted arylsulfenyl, substituted or unsubstituted alkylsulfonyl, substituted or unsubstituted C6-C30 arylsulfonyl, substituted or unsubstituted alkenyl, substituted or unsubstituted aralkyl, substituted or unsubstituted aralkenyl, substituted or unsubstituted alkaryl, substituted or unsubstituted alkylamido, substituted or unsubstituted C1-C30 aralkylamido, substituted or unsubstituted C6-C30 heteroarylamido, substituted or unsubstituted C6-C30 arylamido, substituted or unsubstituted C6-C30 arylheteroarylamido, substituted or unsubstituted C6-C30 arylphosphino, substituted or unsubstituted phosphine oxide group, substituted or unsubstituted C6-C30 aryl, substituted or unsubstituted heterocyclic group, substituted or unsubstituted C1-C30 alkyl C6-C30 diarylsilyl, and substituted or unsubstituted C3-C30 monocyclic or polycyclic alicyclic ring or aromatic ring; and
if at least one of X and Y comprises the substituted or unsubstituted C3-C30 monocyclic or polycyclic alicyclic ring or aromatic ring, the alicyclic ring or aromatic ring comprises at least one heteroatom, and the heteroatom comprises oxygen atom, sulphur atom or nitrogen atom.

15. The light emitting device according to claim 14, wherein R1-R10 individually comprise one of hydrogen, C-C12 alkyl, substituted or unsubstituted C6-C30 arylene and substituted or unsubstituted C3-C30 heteroarylene, and at least one pair of two neighboring groups among R1-R10 are connected to form a ring; and
Ar comprises one of hydrogen, C1-C12 alkyl, substituted or unsubstituted C6-C30 arylene and substituted or unsubstituted C3-C30 heteroarylene.

16. The light emitting device according to claim 12, wherein
0.1 eV<|HOMO_{EBL}−HOMO_{Host}|≤0.3 eV,
wherein HOMO_{EBL} refers to an energy value of a highest occupied molecular orbital HOMO of a material of the electron blocking layer, and HOMO_{Host} refers to an energy value of a highest occupied molecular orbital HOMO of the host material; and
0.1 eV<|LUMO_{HBL}−LUMO_{Host}|≤0.3 eV,
wherein LUMO_{HBL} refers to an energy value of a lowest unoccupied molecular orbital LUMO of a material of the hole blocking layer, and LUMO_{Host} refers to an energy value of a lowest unoccupied molecular orbital LUMO of the host material.

17. The light emitting device according to claim 16, wherein
T1_{EBL}−T1_{TADF}≥0.1eV, and S1_{EBL}−S1_{TADF}>0; and
T1_{HBL}−T1_{TADF}>0, and S1_{HBL}−S1_{TADF}>0;
wherein T1_{EBL} refers to an energy value of a first-triplet-state energy level of the material of the electron blocking layer, T1_{TADF} refers to an energy value of a first-triplet-state energy level of the thermally activated delayed-fluorescence material, S1_{EBL} refers to an energy value of a first-singlet-state energy level of the material of the electron blocking layer, and S1_{TADF} refers to an energy value of a first-singlet-state energy level of the thermally activated delayed-fluorescence material; and
T1_{HBL} refers to an energy value of a first-triplet-state energy level of a material of a hole blocking layer, and S1_{HBL} refers to an energy value of a first-singlet-state energy level of the material of the hole blocking layer.

18. The light emitting device according to claim 17, wherein the light emitting device further comprises a hole transporting layer, and the hole transporting layer is located between the electron blocking layer and the first electrode;
0.1 eV<|HOMO_{HTL}−HOMO_{EBL}|≤0.3 eV,
wherein HOMO_{HTL} refers to an energy value of a highest occupied molecular orbital HOMO of a material of the hole transporting layer;
the light emitting device further comprises an electron transporting layer, and the electron transporting layer is located between the hole blocking layer and the second electrode; and
0.1 eV<|LUMO_{HBL}−LUMO_{ETL}|≤0.3 eV,
wherein LUMO_{ETL} refers to an energy value of a lowest unoccupied molecular orbital LUMO of a material of the electron transporting layer.

19. The light emitting device according to claim 12, wherein
a thickness of the luminescent layer in a direction perpendicular to a plane where the first electrode is located ranges 15 nm-45 nm;
a thickness of the electron blocking layer in the direction perpendicular to the plane where the first electrode is located ranges 1 nm-15 nm; and
a thickness of the hole blocking layer in the direction perpendicular to the plane where the first electrode is located ranges 1 nm-15 nm.

20. A displaying device, wherein the displaying device comprises the light emitting device according to claim 1.
